(19) United States
(12) Patent Application Publication
(10) Pub. No.: US 2026/0130296 A1
(43) Pub. Date: May 7, 2026

(54) POWER MODULE WITH VERTICAL POWER PATHS

(71) Applicant: Monolithic Power Systems, Inc., Kirkland, WA (US)

(72) Inventor: Ting Ge, San Jose, CA (US)

(21) Appl. No.: 19/435,688

(22) Filed: Dec. 29, 2025

Related U.S. Application Data
(63) Continuation-in-part of application No. 18/661,267, filed on May 10, 2024.
Application No. 18/661,267 is a continuation-in-part of application No. 18/469,800, filed on Sep. 19, 2023.

(51) Int. Cl. H10W 90/00; H02M 1/088; H10D 80/20; H10D 80/30; H10W 40/20; H10W 70/60; H10W 72/00; H10W 72/20; H10W 72/30

(52) U.S. Cl. CPC H10W 90/738; H10D 80/211; H10D 80/215; H10D 80/30; H10W 40/242; H10W 70/614; H10W 72/252; H10W 72/365; H10W 72/801; H10W 72/877; H10W 90/724; H02M 1/088

(57) ABSTRACT

A power module has an inductor assembly and a device assembly beneath it. The inductor assembly has a magnetic core with a winding at least partially embedded. The winding has a first end and a second end exposed on a bottom surface of the inductor assembly, and the first end provides an output voltage. The device assembly has a die substrate, a first power die having a first switch, and a second power die having a second switch. The switches are electrically connected in series between an input voltage and ground reference. The second power die is embedded in the die substrate, having metal contacts on both its top side and bottom side. A first plurality of metal contacts of the first power die and the metal contacts on the top side of the second power die are electrically connected together and both to the second end of the winding.

### CROSS-REFERENCE TO RELATED APPLICATIONS

The present application is a continuation-in-part of U.S. application Ser. No. 18/661,267 filed on May 10, 2024, which is a continuation-in-part of U.S. application Ser. No. 18/469,800, filed on Sept. 19, 2023. All of these related applications are incorporated herein by reference in their entirety.

### BACKGROUND OF THE INVENTION

### 1. Field of the Invention

The present invention relates generally to electronic components, and more particularly but not exclusively to power modules.

### 2. Description of Related Art

Power converter, as known in the art, converts an input power to an output power that delivers the voltage and current required by a load. Multi-phase power converters that incorporate a plurality of paralleled power stages operating out of phase exhibit several advantageous attributes: they produce lower output ripple voltage, have improved transient response, and reduce the ripple-current requirements imposed on input filtering capacitors. Because of these performance benefits, such converters are widely deployed in high-current, low-voltage applications including server, microprocessor, and other data-center infrastructure.

The relentless evolution of modern Graphics Processing Units (GPUs), and Central Processing Units (CPUs), has driven a continuous increase in load current to achieve better processor performance. At the same time, the drive for greater integration density imposes strict size constraints on their power converters. Consequently, the combined demands for higher current, smaller form factor, and efficient thermal management present significant design challenges. Therefore, high-power density and high-efficiency power modules with excellent heat dissipation path are necessary for the processers.

### SUMMARY OF THE INVENTION

It is an object of the present invention to provide a power module with vertical power paths.

Embodiments of the present invention are directed to a power module comprising an inductor assembly and a device assembly attached to a bottom surface of the inductor assembly. The inductor assembly has a magnetic core and a first winding at least partially embedded in the magnetic core, wherein the first winding has a first end and a second end which are exposed on the bottom surface of the inductor assembly. The first end of the first winding is capable of providing an output voltage. The device assembly has a die substrate, a first power die, and a second power die. The first power die and the second power die each have a first plurality of metal contacts and a second plurality of metal contacts, and the first power die and the second power die respectively integrates a first switch and a second switch which are electrically connected in series. The first plurality of metal contacts of the first power die and the first plurality of metal contacts of the second power die are electrically connected together and are further electrically connected to the second end of the first winding, wherein the first plurality of metal contacts of the second power die is disposed on a top side of the second power die, and the second power die is embedded in the die substrate. The first power die is capable of receiving an input voltage via its second plurality of metal contacts on its bottom side, and the second power die is capable of being electrically connected to a ground reference via its second plurality of metal contacts on its bottom side.

Embodiments of the present invention are directed to a power module, comprising an inductor assembly and a device assembly attached to a bottom surface of the inductor assembly. The inductor assembly has a magnetic core and a winding at least partially embedded in the magnetic core. The winding has a first end and a second end which are exposed on the bottom surface, and the first end is capable of delivering an output voltage. The device assembly has a die substrate, a first power die that incorporates a first switch, and a second power die that incorporates a second switch. The first and second switches are electrically connected in series between an input voltage and a ground reference. The second power die is embedded in the die substrate and possesses a first plurality of metal contacts on its top side and a second plurality of metal contacts on its bottom side. The first plurality of metal contacts on the first power die and the first plurality of metal contacts on the second power die are electrically connected together and also electrically connect to the second end of the winding.

Embodiments of the present invention are directed to a power module, comprising an inductor assembly and a device assembly attached to a bottom surface of the inductor assembly. The inductor assembly has a magnetic core, a first winding, and a second winding. The first winding and the second winding are at least partially embedded in the magnetic core and each has a first end and a second end exposed on the bottom surface of the inductor assembly. The device assembly has a die substrate, a first power die having a first switch, a second power die having a second switch, a third power die having a third switch, and a fourth power die having a fourth switch. The first switch and the second switch are electrically connected in series between an input voltage and a ground reference, and the third switch and the fourth switch are electrically connected in series between the input voltage and the ground reference. The second power die and the fourth power die are embedded in the die substrate and each has a first plurality of metal contacts on its top side and a second plurality of metal contacts on its bottom side. A first plurality of metal contacts of the first power die and the first plurality of metal contacts of the second power die are electrically connected together and further electrically connected to the second end of the first winding. A first plurality of metal contacts of the third power die and the first plurality of metal contacts of the fourth power die are electrically connected together and further electrically connected to the second end of the second winding.

These and other features of the present invention will be readily apparent to persons of ordinary skill in the art upon reading the entirety of this disclosure, which includes the accompanying drawings and claims.

### BRIEF DESCRIPTION OF THE DRAWINGS

The present invention can be further understood with reference to following detailed description and appended drawings, wherein like elements are provided with like reference numerals. These drawings are only for illustration purpose, thus may only show part of the devices and are not necessarily drawn to scale.

FIG. 1 schematically shows a prior art multi-phase power converter 10 which comprises a controller 101, N power devices 103 and N inductors L for supplying power to a load 104.

FIG. 2 shows a power module 20 for a dual-phase power converter in accordance with an embodiment of the present invention.

FIG. 3 shows a disassembled and perspective view illustrating the power module 20 of FIG. 1.

FIG. 4 shows a cross sectional view illustrating the power module 20 taken along AA′ line of FIG. 1 in accordance with an embodiment of the present invention.

FIG. 5 shows a bottom view of the inductor assembly 203 in accordance with an embodiment of the present invention.

FIG. 6 shows a top view of the device substrate 202 in accordance with an embodiment of the present invention.

FIG. 7 shows a bottom view of the device substrate 202 in accordance with an embodiment of the present invention.

FIG. 8 shows a bottom view of the bottom substrate 201 in accordance with an embodiment of the present invention.

FIG. 9 is a side view illustrating a system 90 employing the power module 20 in accordance with an embodiment of the present invention.

FIG. 10 shows a power module 30 for a dual-phase power converter in accordance with another embodiment of the present invention.

FIG. 11 shows a disassembled and perspective view illustrating the power module 30 of FIG. 10.

FIG. 12 shows a bottom view of the inductor assembly 303 in accordance with an embodiment of the present invention.

FIG. 13 shows a top view of the device substrate 302 in accordance with an embodiment of the present invention.

FIG. 14 shows a bottom view of the device substrate 302 in accordance with an embodiment of the present invention.

FIG. 15 shows a cross-sectional view illustrating the power module 30 taken along CC′ line of FIG. 10 in accordance with an embodiment of the present invention.

FIG. 16 shows a cross-sectional view illustrating the power module 30 taken along DD′ line of FIG. 10 in accordance with an embodiment of the present invention.

FIG. 17 shows a power module 40 for a dual-phase power converter in accordance with another embodiment of the present invention.

FIG. 18 shows a disassembled and perspective view illustrating the power module 40 of FIG. 17.

FIG. 19 shows a bottom view of the inductor assembly 403 in accordance with an embodiment of the present invention.

FIG. 20 shows a bottom view of the device substrate 402 in accordance with an embodiment of the present invention.

FIG. 21 shows a cross-sectional view illustrating the power module 40 taken along EE′ line of FIG. 17 in accordance with an embodiment of the present invention.

FIG. 22 shows a power module 50 for a dual-phase power converter in accordance with another embodiment of the present invention.

FIG. 23 shows a disassembled and perspective view illustrating the power module 50 of FIG. 22.

FIG. 24 shows a bottom view of the inductor assembly 503 in accordance with an embodiment of the present invention.

FIG. 25 shows a bottom view of the device substrate 502 in accordance with an embodiment of the present invention.

FIG. 26 shows a cross-sectional view illustrating the power module 50 taken along FF′ line of FIG. 22 in accordance with an embodiment of the present invention.

FIG. 27 shows a cross-sectional view illustrating the power module 30 taken along GG′ line of FIG. 22 in accordance with an embodiment of the present invention.

FIG. 28 shows a power module 60 for a dual-phase power converter in accordance with an embodiment of the present invention.

FIG. 29 shows a cross-sectional view illustrating the power module 60 taken along HH′ line of FIG. 28 in accordance with an embodiment of the present invention.

FIG. 30 shows a top perspective view of the device assembly 62 in accordance with an embodiment of the present invention.

FIG. 31 shows a cross-sectional view illustrating the power module 60 taken along HH′ line of FIG. 28 in accordance with another embodiment of the present invention.

FIG. 32 schematically shows a multi-phase power converter 10B in accordance with an embodiment of the present invention.

FIG. 33 shows a cross-sectional view illustrating a power module 70A in accordance with an embodiment of the present invention.

FIG. 34 shows a cross-sectional view illustrating a power module 70B in accordance with an embodiment of the present invention.

FIG. 35 shows a cross-sectional view illustrating a power module 70C in accordance with an embodiment of the present invention.

FIG. 36 shows a cross-sectional view illustrating a power module 70D in accordance with an embodiment of the present invention.

FIG. 37 shows a cross-sectional view illustrating a power module 80 in accordance with another embodiment of the present invention.

FIG. 38 shows a top perspective view of a device assembly 82 in accordance with an embodiment of the present invention.

FIG. 39 shows a cross-sectional view illustrating a power module 90A in accordance with an embodiment of the present invention.

FIG. 40 shows a cross-sectional view illustrating a power module 90B in accordance with an embodiment of the present invention.

FIG. 41 shows a cross-sectional view illustrating a power module 90C in accordance with an embodiment of the present invention.

FIG. 42 shows a cross-sectional view illustrating a power module 90D in accordance with an embodiment of the present invention.

### DETAILED DESCRIPTION

In the present disclosure, numerous specific details are provided, such as examples of electrical circuits and components, to provide a thorough understanding of embodiments of the invention. Persons of ordinary skill in the art will recognize, however, that the invention can be practiced without one or more of the specific details. It is noted that, for purposes of illustrative clarity, certain elements in the drawings may not be drawn to scale. In other instances, well-known details are not shown or described to avoid obscuring aspects of the invention.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

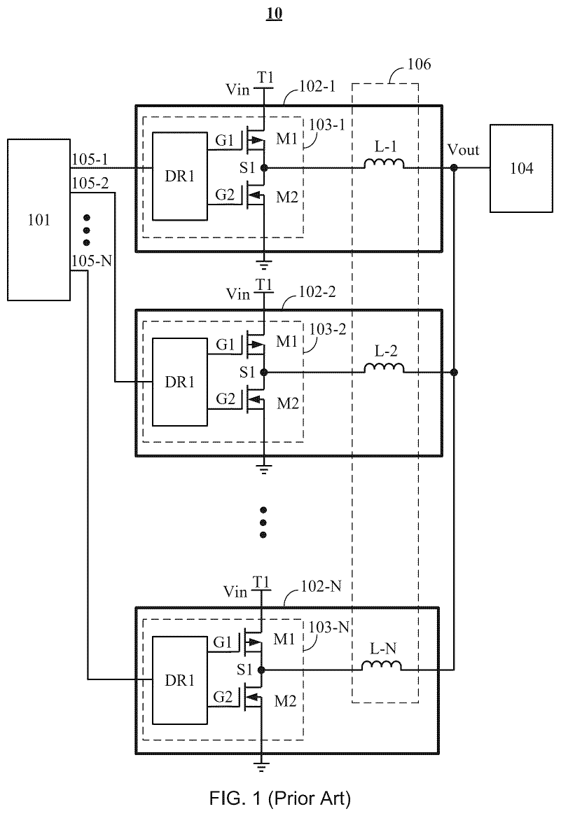

FIG. 1 schematically shows a prior art multi-phase power converter 10 which comprises a controller 101, N power blocks 103-1˜103-N and N inductors L-1˜L-N for supplying power to a load 104, wherein N is an integer, and N≥1. Each power block 103 and one inductor L represent one power stage, i.e., one phase 102 of the power converter 10, as shown in FIG. 1. Each power block 103 includes switches M1, M2 and a driver DR1 for providing driving signals G1 and G2 to drive the switches M1 and M2 respectively. The controller 101 provides N phase control signals 105-1˜105-N respectively to N power blocks 103-1˜103-N to control the N phases b 102-1˜102-N working out of phase, i.e., each one of the inductors L-1˜L-N sequentially absorb power from the input source and sequentially deliver power to the load 104. It should be noticed that the outputs of all phases as shown in FIG. 1 are connected to work as a multi-phase converter. However, each phase output may be separated to work as multiple independent converters which could have different output voltage levels for different load demands.

The power stage 102 with Buck topology is shown in FIG. 1 for example. Persons of ordinary skill in the art should appreciate that power stages with other topologies, like Boost topology, Buck-Boost topology could also be adopted in a multi-phase power converter.

The inductors L-1˜L-N could be implemented by one or a few coupled inductors or could be implemented by N single inductors.

When N=2, the multi-phase power converter 10 is used as a dual-phase power converter or two separate single-phase converters. For the ease of description, dual-phase power module for a dual-phase power converter is discussed as an example to illustrate the present invention.

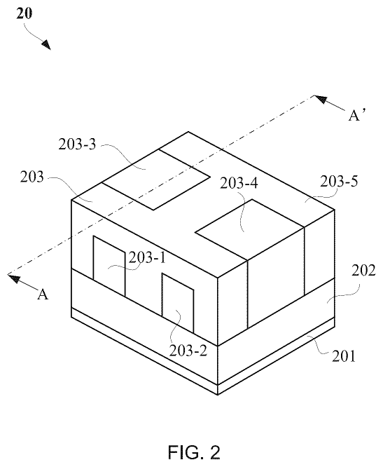

FIG. 2 shows a power module 20 for a dual-phase power converter in accordance with an embodiment of the present invention. The power module 20 may serve as the power stage 102 of FIG. 1, with N=2. The power module 20 includes a bottom substrate 201, a device substrate 202 and an inductor assembly 203. The bottom substrate 201 is arranged at the bottom of the power module 20. The device substrate 202 is arranged on the bottom substrate 201. The inductor assembly 203 is arranged on the device substrate 202. Power device chips integrating the components of the power blocks 103 shown in FIG. 1 is embedded in the device substrate 202. The inductors L are integrated in the inductor assembly 203.

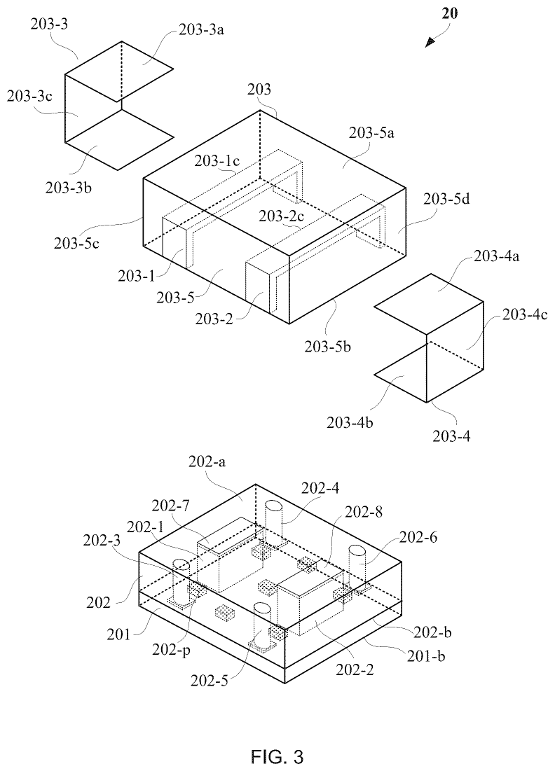

FIG. 3 shows a disassembled and perspective view illustrating the power module 20 of FIG. 2. As shown in FIG. 3, the device substrate 202 includes a first power device chip 202-1, a second power device chip 202-2, a first pair of connecting pillars 202-3 and 202-4, a second pair of connecting pillars 202-5 and 202-6, and a plurality of discrete components 202-p embedded in the device substrate 202. Each one of the first power device chip 202-1 and the second power device chip 202-2 integrates one power block 103 in FIG. 1, which includes the switches M1, M2, the driver DR1, and further integrates some auxiliary circuits not shown in FIG. 1. The first pair of the connecting pillars includes a first connecting pillar 202-3 and a second connecting pillar 202-4 arranged at opposite sides of the first power device chip 202-1. The second pair of the connecting pillars includes a third connecting pillar 202-5 and a fourth connecting pillar 202-6 arranged at opposite sides of the second power device chip 202-2. Each one of the connecting pillars has a first end connecting out of the device substrate 202, and connected to the corresponding winding of the inductor assembly 203, and a second end connected to the bottom substrate 201. The connecting pillars shown in the example of FIG. 3 are cylinders. It should be appreciated that any shape of the connecting pillars is applicable to the present invention. The discrete components 202-p include resistors and capacitors of the power converter 10, like the input capacitors at the input terminal T1 of the power converter 10 for receiving the input voltage Vin to provide pulse current, the filter capacitors and resistors for the drivers DR1 and internal logic circuits power supplies (not shown in FIG. 1), etc.

In the example of FIG. 3, the inductor assembly 203 includes a magnetic core 203-5, a first winding 203-1 and a second winding 203-2 passing through the magnetic core 203-5. The first winding 203-1 and the magnetic core 203-5 form a first inductor L-1 as shown in FIG. 1. The second winding 203-2 and the magnetic core 203-5 form a second inductor L-2 as shown in FIG. 1. Furthermore, the inductor assembly 203 includes a first heat sink layer 203-3 and a second heat sink layer 203-4, each of which has a “C” shape, and partially wraps the magnetic core 203-5. As can be seen from FIG. 3, the first heat sink layer 203-3 has a first portion 203-3a partially covering a first surface 203-5a of the magnetic core 203-5, a second portion 203-3b partially covering a second surface 203-5b of the magnetic core 203-5, and a third portion 203-3c connecting the first portion 203-3a and the second portion 203-3b, and partially covering a third surface 203-5c of the magnetic core 203-5, wherein the first surface 203-5a and the second surface 203-5b are opposite, and the third surface 203-5c is vertical to the first surface 203-5a and the second surface 203-5b. The second heat sink layer 203-4 has a first portion 203-4a partially covering the first surface 203-5a, a second portion 203-4b partially covering the second surface 203-5b, and a third portion 203-4c connecting the first portion 203-4a and the second portion 203-4b, and covering a fourth surface 203-5d of the magnetic core 203-5, wherein the fourth surface 203-5d is opposite to the third surface 203-5c, and is vertical to the first surface 203-5a and the second surface 203-5b of the magnetic core 203-5. The surfaces of the magnetic core 203-5 are also referred as surfaces of the inductor module 203. It should be appreciated that the first heat sink layer 203-3 and the second heat sink layer 203-4 are configured for transferring heat from the power device chips to the environment or external components. The shape of the first heat sink layer 203-3 and the second heat sink layer 203-4 may be varying in different applications, e.g., the first heat sink layer 203-3 may have a “L” shape with the second portion 203-3b and the third portion 203-3c, and similarly, the second heat sink layer 203-4 may have a “L” shape with the second portion 203-4b and the third portion 203-4c.

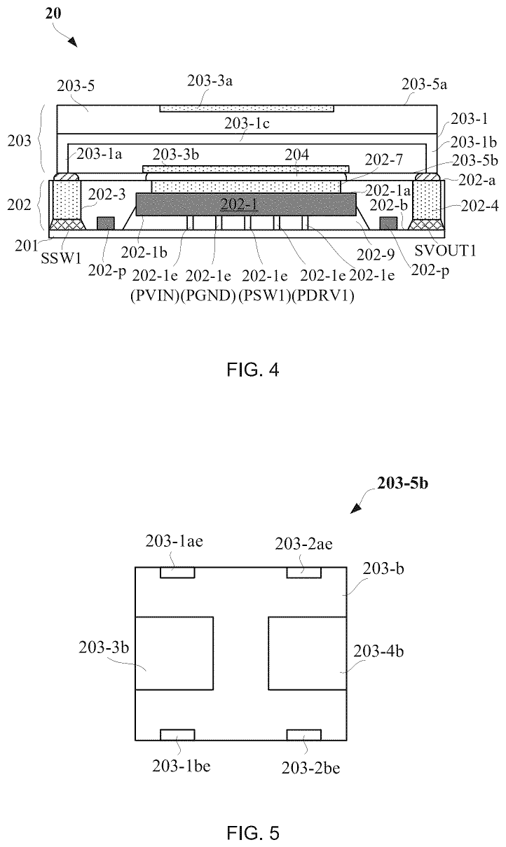

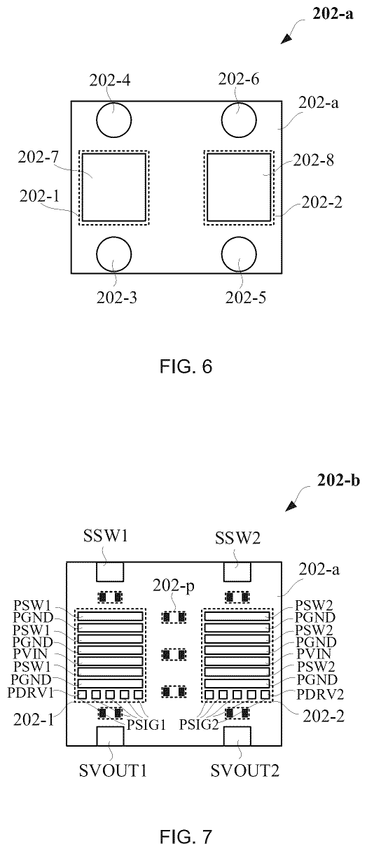

FIG. 4 shows a cross-sectional view illustrating the power module 20 taken along AA′ line of FIG. 2 in accordance with an embodiment of the present invention. FIG. 5 shows a bottom view of the inductor assembly 203, i.e., the second surface 203-5b of the inductor assembly 203, in accordance with an embodiment of the present invention. FIG. 6 shows a top view of the device substrate 202, i.e., the first surface 202-a of the device substrate 202, in accordance with an embodiment of the present invention. FIG. 7 shows a bottom view of the device substrate 202, i.e., the second surface 202-b of the device substrate 202, in accordance with an embodiment of the present invention. The structure of the power module 20 will be illustrated with reference to FIGS. 3˜7.

As shown in FIG. 4, the first power device chip 202-1 has a first surface 202-1a and a second surface 202-1b. The first surface 202-1a is covered by a top heat layer 202-7 as shown in FIGS. 4 and 6, and the second surface 202-1b has a plurality of pins 202-1e (including pins PVIN, PGND, PSW1, PDRV1, and etc.) exposed on the second surface 202-b of the device substrate 202 as shown in FIGS. 4 and 7, and connected to the bottom substrate 201. Similarly, The first surface 202-2a of the second power device chip 202-2 is covered by a top heat layer 202-8 as shown in FIG. 6, and the second surface 202-2b of the second power device chip 202-2 has a plurality of pins 202-2e (including pins PVIN, PGND, PSW2, PDRV2, and etc.) exposed on the second surface 202-b of the device substrate 202 as shown in FIG. 7, and connected to the bottom substrate 201. It should be appreciated that the pins shown in FIGS. 4 and 7 are for illustration purpose. More pins may be configured in a real application. Furthermore, the pin shape, the pin size and the pin distribution would be varying in different applications. The top heat layer 202-7 and the top heat layer 202-8 are heat disposal layers, which are made of copper in one embodiment, and are made of other material in other embodiments. Persons of ordinary skill in the art should appreciate that any suitable layer configured to transfer heat from the power device chip is applicable as the top heat layer. In one embodiment, the first portion 203-3a of the first heat sink layer 203-3 and the first portion 203-4a of the second heat sink layer 203-4 are extending to each other and merged as one piece. In one embodiment, the second portion 203-3b of the first heat sink layer 203-3 and the second portion 203-4b of the second heat sink layer 203-4 are extending to each other and merged as one piece. In one embodiment, the first portion 203-3a of the first heat sink layer 203-3 and the first portion 203-4a of the second heat sink layer 203-4 are removed, and a heat radiator may remove heat from the first power device chip 202-1 and the second power device chip 202-2 via the third portion 203-3c of the first heat sink layer 203-3 and the third portion 203-4c of the second heat sink layer 203-4. Similarly, the top heat layer 202-7 and the top heat layer 202-8 could be merged as a whole piece.

As mentioned before, the first power device chip 202-1 integrates the switches M1, M2, the driver DR1 shown in FIG. 1, and other accessory circuits not shown in FIG. 1. The plurality of pins 202-1e of the first power device chip 202-1 includes at least an input pin PVIN, a switching pin PSW1, a ground pin PGND, and a driving pin PDRV1 as shown in FIG. 7. The first switch M1 has a first terminal coupled to the input pin PVIN (corresponding to the input terminal T1 in FIG. 1) to receive the input voltage Vin (shown in FIG. 1), a second terminal connected to the switching pin PSW1 (corresponding to the switching terminal S1 in FIG. 1), and a control terminal configured to receive a first driving signal G1. The second switch M2 has a first terminal connected to the switching pin PSW1, a second terminal connected to the ground pin PGND, and a control terminal configured to receive a second driving signal G2. The driver DR1 is coupled to the driving pin PDRV1 to receive a phase control signal 105, and to provide the first driving signal G1 and the second driving signal G2 based on the phase control signal 105. The plurality of pins of the power device chips 202-1 and 202-2 are electrically connected to external circuits/devices/components via the bottom substrate 201. The bottom substrate 201 may be attached to a mainboard where the load (CPU, GPU, etc.) located, and there may be circuits/devices/components on the mainboard providing the input voltage Vin, the phase control signal 105, and a ground reference GND that provides a common ground for the first power device chip 202-1 and the second power device chip 202-2 via the ground pins PGND.

It should be appreciated that the second power device chip 202-2 has the same structure as the first power device chip 202-1, and is not discussed for the brevity of description.

The first winding 203-1 and the second winding 203-2 are embedded in the magnetic core 203-5 and have an upside-down “U” shape, and are parallel to each other. In the example shown in FIG. 4, the first winding 203-1 has a first portion 203-1a and a second portion 203-1b having ends 203-1ae and 203-1be connected out of the second surface 203-5b of the magnetic core 203-5, and has a middle portion 203-1c parallel to the first surface 203-5a of the magnetic core 203-5 and connecting the first portion 203-1a and the second portion 203-1b. The end 203-1ae of the first portion 203-1a of the first winding 203-1 connects out of the second surface 203-5b of the magnetic core 203-5 as shown in FIG. 5, and is electrically connected to the first connecting pillar 202-3 embedded in the device substrate 202 by soldering or other connecting means as shown in FIG. 4. The end 203-1be of the second portion 203-1b of the first winding 203-1 connects out of the second surface 203-5b of the magnetic core 203-5 as shown in FIG. 5, and is electrically connected to the second connecting pillar 202-4 embedded in the device substrate 202 by soldering or other connecting means as shown in FIG. 4. It should be appreciated that the second winding 203-2 has the similar structure with the first winding 203-1 as shown in FIG. 3, and has two ends 203-2ae and 203-2be electrically connected to third connecting pillar 202-5 and the fourth connecting pillar 202-6 respectively.

The second portion 203-3b of the first heat sink layer 203-3 partially covers the second surface 203-5b of the magnetic core 203-5 as shown in FIG. 5, and is attached to the top heat layer 202-7 directly or via a heat conductive contact 204 as shown in the example of FIG. 4. Similarly, the second portion 203-4b of the second heat sink layer 203-4 partially covers the second surface 203-5b of the magnetic core 203-5 as shown in FIG. 5, and is attached to a top heat layer on top of the second power device chip 202-2 directly or via a heat conductive contact. In one embodiment, the heat sink layers 203-3 and 203-4 are made of copper, and dissipate heat from the top heat layers on top of the power device chips 202-1 and 202-2. Consequently, the heat of the power device chips 202-1 and 202-2 are dissipated via the top heat layers 202-7 and 202-8 and the heat sink layer 203-3 and 203-4, respectively. The heat sinks 203-3 and 203-4 are attached to the magnetic core 203-5 by either thermal glue, thermal paste, or direct contact.

The first connecting pillar 202-3 has one end connecting out of the first surface 202-a of the device substrate 202 as shown in FIG. 6, and connected to the end of the first portion 203-1a of the first winding 203-1 as shown in FIG. 4, and has the other end connected to the bottom substrate 201 via a first switching terminal SSW1. Furthermore, the end of the first portion 203-1a of the first winding 203-1, and the first connecting pillar 202-3, are electrically connected to the switching pin PSW1 of the first power device chip 202-1 via conductive traces inside the bottom substrate 201. Consequently, the heat of the first power device chip 202-1 is further dissipated through the first connecting pillar 202-3 and the first winding 203-1. The second connecting pillar 202-4 has one end connecting out of the first surface 202-a of the device substrate 202 and connected to the end of the second portion 203-1b of the first winding 203-1, and has the other end connected to the bottom substrate 201 via a first output voltage terminal SVOUT1. The third connecting pillar 202-5 has one end connecting out of the first surface 202-a of the device substrate 202 as shown in FIG. 6, and connected to the end 203-2ae of the first portion 203-2a of the second winding 203-2 shown in FIG. 5, and has the other end connected to the bottom substrate 201 via a second switching terminal SSW2. The end 203-2ae of the first portion 203-2a of the second winding 203-2, and the third connecting pillar 202-5, are electrically connected to the switching pin PSW2 of the second power device chip 202-2 via conductive traces inside the bottom substrate 201. Consequently, the heat of the second power device chip 202-2 is further dissipated through the third connecting pillar 202-5 and the second winding 203-2. The fourth connecting pillar 202-6 has one end connecting out of the first surface 202-a of the device substrate 202 and connected to the end 203-2be of the second portion 203-2b of the second winding 203-2, and has the other end connected to the bottom substrate 201 via a second output voltage terminal SVOUT2. In some embodiments of the present invention, the connecting pillars 202-3˜202-6 are soldered to the bottom substrate 201, and the first switching terminal SSW1, the first output voltage terminal SVOUT1, the second switching terminal SSW2 and the second output voltage terminal SVOUT2 are solder pastes at the ends of the connecting pillars 202-3˜202-6. It should be appreciated that the connecting pillars 202-3˜202-6 may be connected to the bottom substrate 201 directly, or by other connecting means known in the art, e.g., the connecting pillars 202-3˜202-6 may be protruded out of the bottom surface 202-b of the device substrate 202, and are inserted to grooves of the bottom substrate 201.

As shown in FIG. 7, the first power device chip 202-1 has signal pins PSIG1 which may be configured to transmit temperature monitoring signal, current monitoring signal, and other necessary signals for communicating between the first power device chip 202-1 and external circuits. The second power device chip 202-2 has signal pins PSIG2 which may be configured to transmit temperature monitoring signal, current monitoring signal, and other necessary signals for communicating between the second power device chip 202-2 and external circuits. In FIG. 7, the driving pin PDRV1 is illustrated as an example of signal pins PSIG1, and the driving pin PDRV2 is illustrated as an example of signal pins PSIG2. Other signal pins, like the pins for transmitting the temperature monitoring signal, the current monitoring signal, etc., are not specifically labeled for brevity. The discrete components 202-p together with the power device chips 202-1 and 202-2 which are molded within the device substrate 202 have connecting terminals on the second surface of the device substrate 202. As shown in the embodiment of FIG. 7, each one of the discrete components 202-p, i.e., the capacitors and the resistors, has two pins or pads exposed on the second surface 202-b of device substrate 202, and connected to the bottom substrate 201, wherein the discrete components 202-p are electrically connected to the power device chips 202-1, 202-2, and external components/circuits via the bottom substrate 201. Persons of ordinary skill in the art should know that the pins shown in FIG. 7 are for illustrating, which should not be limiting the present invention. The pin distribution on the second surface of the device substrate 202 is determined by the requirement of the application specs, and is varying in different applications.

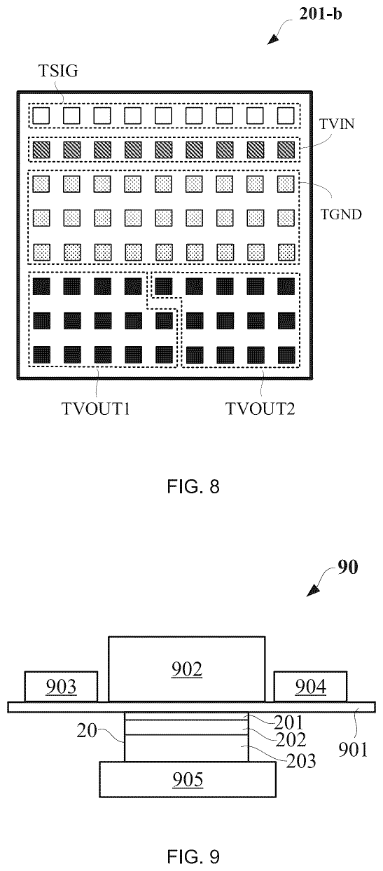

FIG. 8 shows a bottom view of the bottom substrate 201, i.e., the second surface 201-b of the bottom substrate 201, in accordance with an embodiment of the present invention. The second surface 201-b of the bottom substrate 201 includes a signal pad area TSIG, an input pad area TVIN, a ground pad area TGND, a first output voltage pad area TVOUT1 and a second output voltage pad area TVOUT2. Each one of the pad areas includes a plurality of pads. The pads on the second surface 201-b of the bottom substrate 201 connect through to the first surface 201-a of the bottom substrate 201 using, e.g., vias and conductive traces inside the bottom substrate 201. The plurality of pads of the signal pad area TSIG are electrically connected to the signal pins PSIG1 of the first power device chip 202-1 and the signal pins PSIG2 of the second power device chip 202-2 respectively, like the driving pins PDRV1, PDRV2, temperature monitoring pins, etc. The plurality of pads of the input pad area TVIN are electrically connected to the input pins PVIN of the first power device chip 202-1 and the second power device chip 202-2. The plurality of pads of the ground pad area TGND are electrically connected to the ground pins PGND of the first power device chip 202-1 and the second power device chip 202-2. The plurality of pads of the first output voltage pad area TVOUT1 are electrically connected to the end of the second portion 203-1b of the first winding 203-1 via the second connecting pillar 202-4. The plurality of pads of the second output voltage pad area TVOUT2 are electrically connected to the end of the second portion 203-2b of the second winding 203-2 via the fourth connecting pillar 202-6. In one embodiment, the pads of the first output voltage pad area TVOUT1 and the pads of the second output voltage pad area TVOUT2 are electrically disconnected, which makes the power module 20 work as two independent converters. In some embodiments, the pads of the first output voltage pad area TVOUT1 and the pads of the second output voltage pad area TVOUT2 are electrically connected by external conductive traces or traces inside the bottom substrate, which makes the power module 20 work as a dual-phase power converter.

In the present invention, by stacking the bottom substrate 201, the device substrate 202 and the inductor assembly 203 vertically, the power density is increased. The first portions and the second portions of the first winding and the second winding are exposed to the side surfaces of the magnetic core as shown in the embodiments of the present invention. It should be appreciated that the first portions and the second portions of the first winding and the second winding could be totally embedded inside the magnetic core, thereby switching noise is shielded by the magnetic core 205 and the device substrate 202 of the power module 20, thus better noise immunity is provided compared to the prior art power modules.

In the present invention, the power device chips embedded in the device substrate dissipate heat from the top, i.e., through the top heat layers, and meanwhile from the bottom, i.e., through the pins attached to the bottom substrate, and then further through the windings and magnetic core of the inductor assembly, which makes the heat dissipation performance excellent.

In one embodiment, the device substrate 202 is formed by firstly attaching the power device chips 202-1 and 202-2, the discrete components 202-p, and the connecting pillars 202-3˜202-6 to the bottom substrate 201, and secondly molding all the aforementioned components together. The power module 20 could be produced by stacking the inductor module 203 on top (first surface 202-a) of the device substrate 202, which highly eases the manufacturability and improves the robustness.

It should be appreciated that the device substrate 202 could also be implemented by other means, e.g., by PCB (Printed Circuit Board) process. Specifically, the power device chips 202-1 and 202-2, the discrete components 202-p, and the connecting pillars 202-3˜202-6 could be integrated in a PCB or be embedded by several PCB layers.

In one embodiment, the bottom substrate 201 is implemented by a PCB layer.

FIG. 9 is a side view illustrating a system 90 employing the power module 20 in accordance with an embodiment of the present invention. The system 90 includes a mainboard 901, a load 902, external components 903, 904, the power module 20, and a heat radiator 905. In the embodiment of FIG. 9, the load 902 and the power module 20 are attached to the opposite surfaces of the mainboard 901, which shorts the power delivery path, and improves the power efficiency. The load 902 may be a CPU, a GPU, or any other microprocessors. The power module 20 is attached to the mainboard 901 by the bottom substrate 201. The top of the power module 20 is covered by the heat radiator 905 for heat dissipation. The external components 903 and 904 may be the devices providing power, i.e., the input voltage Vin, or providing the phase control signals 105, to the power module 20. In other embodiments, the power module 20 and the load 902 may be placed on the same surface of the mainboard 901.

The power module for the dual-phase power converter is described for illustrating the present invention. It should be appreciated that the power module in the present invention could be scaled in by including a single power device chip and a single inductor to implement a single-phase power converter, or be scaled out by including more power device chips and inductors to implement multiple power converters or a multi-phase power converter.

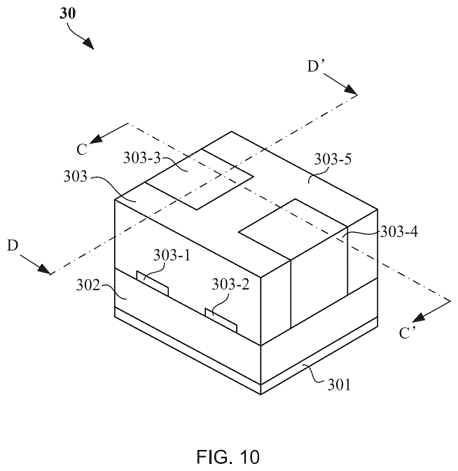

FIG. 10 shows a power module 30 for a dual-phase power converter in accordance with another embodiment of the present invention. The power module 30 may serve as the power stage 102 of FIG. 1, with N=2. The power module 30 includes a bottom substrate 301, a device substrate 302 and an inductor assembly 303. As shown in FIG. 10, the power module 30 has a stacked structure, i.e., the bottom substrate 301 is arranged at the bottom of the power module 30, having a first surface facing the device substrate 302 and a second surface opposite to the first surface for external connection, the device substrate 302 is arranged on the bottom substrate 301, and the inductor assembly 303 is arranged on the device substrate 302. The inductor assembly 303 comprises a first winding 303-1, a second winding 303-2 and a magnetic core 303-5, thus the inductors L (e.g., L-1 and L-2) are integrated in the inductor assembly 303. In the example of FIG. 10, the inductor assembly 303 further comprises heat sink layers 303-3 and 303-4.

In one embodiment, the second surface of the bottom substrate 301 of the power module 30 comprises a first output voltage pad area and a second output voltage pad area, an input pad area, a ground pad area and a signal pad area, wherein structure and connection of the pad areas on the second surface of the bottom substrate 301 are same as the pad areas on the second surface 201-b of the bottom surface 201 described previously in FIG. 8, and is not discussed for the brevity of description.

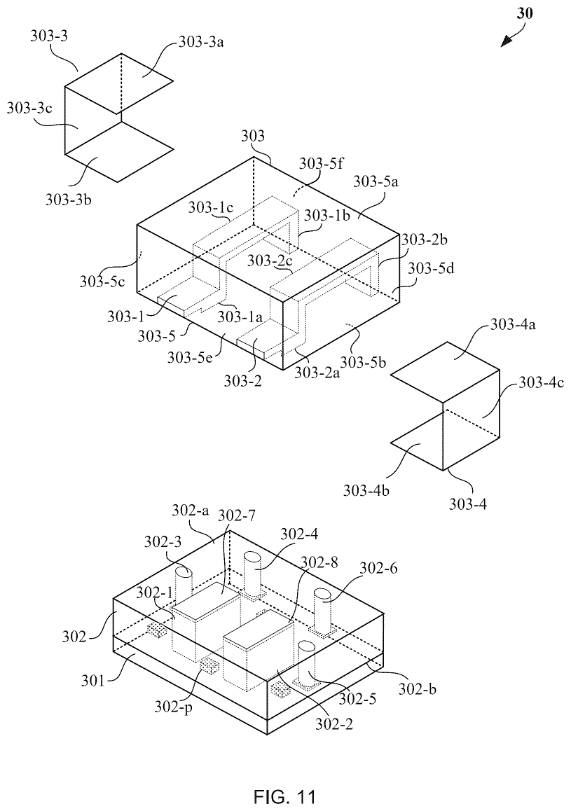

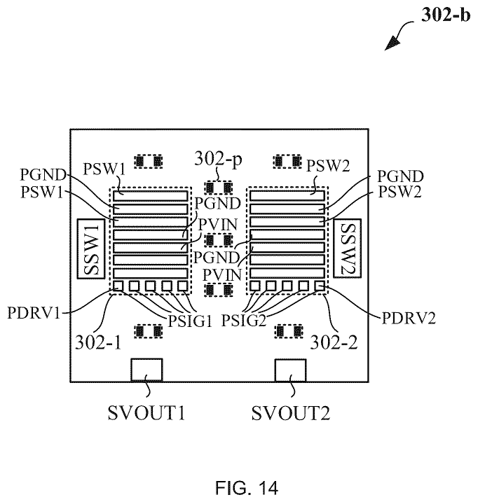

FIG. 11 shows a disassembled and perspective view illustrating the power module 30 of FIG. 10. As shown in FIG. 11, the device substrate 302 includes a first power device chip 302-1, a second power device chip 302-2, connecting pillars 302-3, 302-4, 302-5 and 302-6, and a plurality of discrete components 302-p, wherein all these components of the device substrate 302 are at least partially embedded in the device substrate 302. Each one of the first power device chip 302-1 and the second power device chip 302-2 integrates one power block 103 in FIG. 1, which includes the switches M1, M2, the driver DR1, and further integrates some auxiliary circuits not shown in FIG. 1. As shown in FIG. 11, the device substrate 302 has a first surface 302-a and a second surface 302-b opposite to the first surface 302-a. The first power device chip 302-1 is at least partially covered by a top heat layer 302-7, and the second power device chip 302-2 is at least partially covered by a top heat layer 302-8. Each of the top heat layers 302-7 and 302-8 has a surface exposed on the first surface 302-a of the device substrate 302. In the example of FIG. 11, a switching pin of the first power device chip 302-1 is electrically coupled to the top heat layer 302-7, e.g., via conductive traces in the bottom substrate 301, the connecting pillar 302-3 and the heat sink layer 303-3, and similarly, a switching pin of the second power device chip 302-2 is electrically coupled to the top heat layer 302-8, e.g., via conductive traces in the bottom substrate, the connecting pillar 302-5 and the heat sink layer 303-4, which will be further illustrated beginning with FIG. 14. Each of the connecting pillars 302-3, 302-4, 302-5, and 302-6 has a first end exposed on the first surface 302-a of the device substrate 302 to connect with the inductor assembly 303, and has a second end exposed on the second surface 302-b of the device substrate 302 to connect with the bottom substrate 301. The connecting pillars shown in the example of FIG. 11 are cylinders, and it should be appreciated that any shape of the connecting pillars is applicable to the present invention. The discrete components 302-p include resistors and capacitors of the power converter 10, like the input capacitors at the input terminal T1 of the power converter 10 for receiving the input voltage Vin to provide pulse current, the filter capacitors and resistors for the drivers DR1 and internal logic circuits power supplies (not shown in FIG. 1), etc.

In the example of FIG. 11, the first winding 303-1 and the second winding 303-2 pass through the magnetic core 303-5. The first winding 303-1 and the magnetic core 303-5 form the first inductor L-1 as shown in FIG. 1. The second winding 303-2 and the magnetic core 303-5 form the second inductor L-2 as shown in FIG. 1. In one embodiment, the first winding 303-1 and the second winding 303-2 are made of copper. Furthermore, each of the heat sink layers 303-3 and 303-4 has a “C” shape and wraps at least partial of the magnetic core 303-5. As can be seen from FIG. 11, the heat sink layer 303-3 has a portion 303-3a covering at least partial of a first surface 303-5a of the magnetic core 303-5, a portion 303-3b covering at least partial of a second surface 303-5b of the magnetic core 303-5, and a portion 303-3c connecting the portions 303-3a and 303-3b and covering at least partial of a third surface 303-5c of the magnetic core 303-5. The first surface 303-5a and the second surface 303-5b are opposite, and the third surface 303-5c is vertical to the first surface 303-5a and the second surface 303-5b. The heat sink layer 303-4 has a portion 303-4a covering at least partial of the first surface 303-5a, a portion 303-4b covering at least partial of the second surface 303-5b, and a portion 303-4c connecting the portions 303-4a and 303-4b, and covering at least partial of a fourth surface 303-5d of the magnetic core 303-5, wherein the fourth surface 303-5d is opposite to the third surface 303-5c, and is vertical to the first surface 303-5a and the second surface 303-5b of the magnetic core 303-5. As shown in FIG. 11, the magnetic core 303-5 further has a fifth surface 303-5e and a sixth surface 303-5f which are opposite to each other, and are vertical to the first surface 303-5a and the second surface 303-5b of the magnetic core 303-5. The surfaces of the magnetic core 303-5 are also referred as surfaces of the inductor assembly 303. The shapes of the heat sink layers 303-3 and 303-4 may be varying in different applications, e.g., the heat sink layer 303-3 may have a “L” shape with the portion 303-3b and the portion 303-3c, and similarly, the heat sink layer 303-4 may have a “L” shape with the portion 303-4b and the portion 303-4c. In one embodiment, the heat sink layers 303-3 and 303-4 are made of copper.

In the example of FIG. 11, the first winding 303-1 and the second winding 303-2 are at least partially embedded in the magnetic core 303-5, e.g., each of the first winding 303-1 and the second winding 303-2 may have at least a part exposed on one or more surfaces of the magnetic core 303-5. In the example shown in FIG. 11, the first winding 303-1 has a first portion 303-1a, a second portion 303-1b, and a third portion 303-1c connecting the first portion 303-1a and the second portion 303-1b. Similarly, the second winding 303-2 has a first portion 303-2a, a second portion 303-2b, and a third portion 303-2c connecting the first portion 303-2a and the second portion 303-2b. The third portion 303-1c of the first winding 303-1 and the third portion 303-2c of the second winding 303-2 are parallel to each other, and each has a top surface which is parallel to the first surface 303-5a of the magnetic core 303-5. Each of the first portion and the second portion of the first winding 303-1 has a part exposed on the second surface 303-5b of the magnetic core 303-5, and each of the first portion and the second portion of the second winding 303-2 has a part exposed on the second surface 303-5b of the magnetic core 303-5. In one embodiment, each of the first portions of the first winding 303-1 and the second winding 303-2 further has a part exposed on the fifth surface 303-5e, and each of the second portions of the first winding 303-1 and 303-2 further has a part exposed on the sixth surface 303-5e.

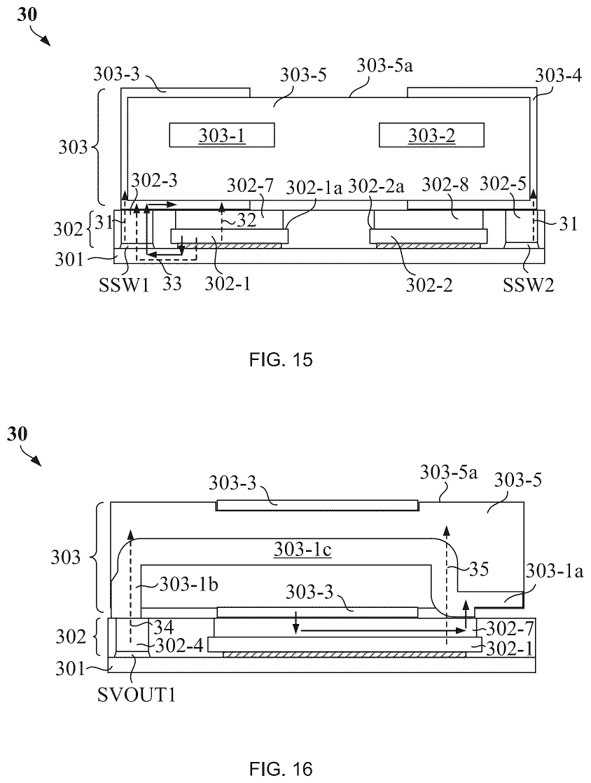

When the bottom substrate 301, the device substrate 302 and the inductor assembly 303 are assembled together, the second surface 302-b of the device substrate 302 faces the first surface of the bottom substrate 301, and the second surface 303-5b of the inductor assembly 303 faces the first surface 302-a of the device substrate 302. The first portion 303-1a of the first winding 303-1 is electrically connected to the top heat layer 302-7, and the first portion 303-2a of the second winding 303-2 is electrically connected to the top heat layer 302-8. The second portion 303-1b of the first winding 303-1 is electrically connected to the connecting pillar 302-4, and the second portion 303-2b of the second winding 303-2 is electrically connected to the connecting pillar 302-6. The second portion 303-1b of the first winding 303-1 and the second portion 303-2b of the second winding 303-2 are electrically connected to the first output voltage pad area and the second output voltage pad area respectively via the device substrate and the bottom substrate. The portion 303-3b of the heat sink layer 303-3 is electrically connected to the connecting pillar 302-3 and the top heat layer 302-7, and the portion 303-4b of the heat sink layer 303-4 is electrically connected to the connecting pillar 302-5 and the top heat layer 302-8. In one embodiment, the portion 303-3b of the heat sink layer 303-3 is physically attached to the first end of the connecting pillar 302-3 by soldering or via a conductive adhesive, and the portion 303-4b of the heat sink layer 303-4 is physically attached to the first end of the connecting pillar 302-5 by soldering or via a conductive adhesive. By electrically connecting the heat sink layers 303-3 and 303-4 to the device substrate 302, the heat sink layers 303-3 and 303-4 are configured for transferring both heat and current. To be specific, when the power module is powered on, the heat sink layer 303-3 and the heat sink layer 303-4 transfer heat from the first power device chip 302-1 and the second power device chip 302-2 to the environment or external components, and also transfer current from the first power device chip 302-1 and the second power device chip 302-2 to the first winding 303-1 and the second winding 303-2. Thus the thermal flow of the power module 300 is optimized, as will be further illustrated beginning with FIG. 15.

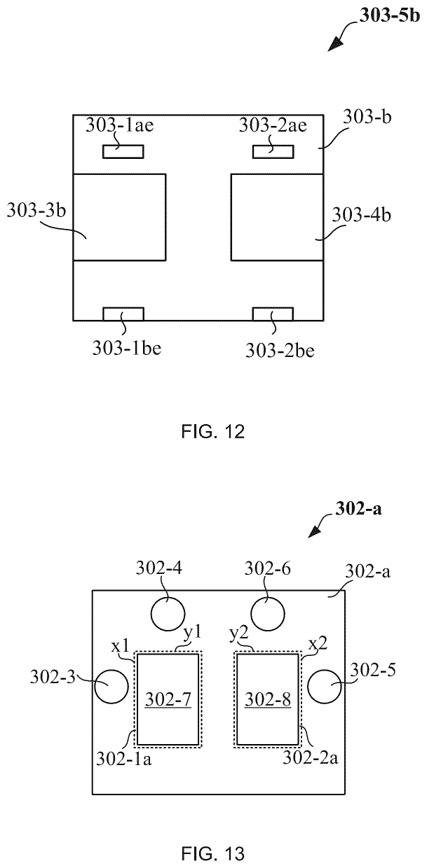

FIG. 12 shows a bottom view of the inductor assembly 303, i.e., the second surface 303-5b of the inductor assembly 303, in accordance with an embodiment of the present invention. In the example shown in FIG. 12, the first portion 303-1a of the first winding 303-1 has an end 303-1ae, and the second portion 303-1b of the first winding 303-1 has an end 303-1be. The end 303-1ae of the first portion 303-1a of the first winding 303-1 is exposed on the second surface 303-5b of the magnetic core 303-5 as shown in FIG. 12, and is electrically connected to the top heat layer 302-7. The end 303-1be of the second portion 303-1b of the first winding 303-1 is exposed on the second surface 303-5b of the magnetic core 303-5 and is electrically connected to the connecting pillar 302-4. In one embodiment, the end 303-1ae of the first portion 303-1a of the first winding 303-1 is physically attached to the surface of the top heat layer 302-7 by soldering or via a conductive adhesive, and the end 303-2be of the second winding 303-2 is physically attached to the connecting pillar 302-6 by soldering or via a conductive adhesive. It should be appreciated that the second winding 303-2 has the similar structure with the first winding 303-1 as shown in FIG. 11, and has an end 303-2ae electrically connected to the top heat layer 302-8 and another end 303-2be electrically connected to the connecting pillar 302-6. In one embodiment, the end 303-2ae of the second winding 303-2 is physically attached to the surface of the top heat layer 302-8 by soldering or via a conductive adhesive, and the end 303-2be of the second winding 303-2 is physically attached to the connecting pillar 302-6 by soldering or via a conductive adhesive.

FIG. 13 shows a top view of the device substrate 302 in accordance with an embodiment of the present invention. FIG. 13 shows a top surface 302-1a of the first power device chip 302-1 which is partially covered by the top heat layer 302-7, and a top surface 302-2a of the second power device chip 302-2 which is partially covered by the top heat layer 302-8. As shown in FIG. 13, the top surface 302-1a of the first power device chip 302-1 has a long edge x1 and a short edge y1, and the top surface 302-2a of the second power device chip 302-2 has a long edge x2 and a short edge y2. Different from the power module 20 described in previous embodiments in which the connecting pillars are arranged next to opposite edges of a top surface of the corresponding power device chip, in the embodiment of FIG. 13, the connecting pillars 302-3 and 302-4 of the power module 30 are arranged next to adjacent edges of the top surface 302-1a of the first power device chip 302-1, i.e., the connecting pillar 302-3 is placed next to the long edge x1 of the top surface 302-1a of the first power device chip 302-1, and the connecting pillar 302-4 is placed next to the short edge y1 of the top surface 302-1a of the first power device chip 302-1. Similarly, the connecting pillar 302-5 is placed next to the long edge x2 of the top surface 302-2a of the second power device chip 302-2, and the connecting pillar 302-6 is placed next to the short edge y2 of the top surface 302-2a of the second power device chip 302-2.

FIG. 14 shows a bottom view of the device substrate 302 in accordance with an embodiment of the present invention. As mentioned before, each of the first power device chip 302-1 and the second power device chip 302-2 integrates the switches M1, M2, the driver DR1 shown in FIG. 1 and other accessory circuits. Therefore, each of the first power device chip 302-1 and the second power device chip 302-2 has a plurality of pins including at least an input pin PVIN, at least one switching pin PSW1, at least one ground pin PGND, and a driving pin PDRV1 as shown in FIG. 14 (not all of the switching pins PSW1 and ground pins PGND are labeled in FIG. 14 for clarity of illustration). Taking the first power device chip 302-1 as an example, a common node of the switches M1 and M2 is connected to the at least one switching pin PSW1. To be specific, the first switch M1 has a first terminal coupled to the input pin PVIN (corresponding to the input terminal T1 in FIG. 1) to receive the input voltage Vin (shown in FIG. 1), a second terminal connected to the at least one switching pin PSW1 (corresponding to the switching terminal S1 in FIG. 1), and a control terminal configured to receive a first driving signal G1. The second switch M2 has a first terminal connected to the at least one switching pin PSW1, a second terminal connected to the ground pin PGND, and a control terminal configured to receive a second driving signal G2. The driver DR1 is coupled to the driving pin PDRV1 to receive a phase control signal 105 shown in FIG. 1, and to provide the first driving signal G1 and the second driving signal G2 based on the phase control signal 105. The plurality of pins of the first power device chip 302-1 and the second power device chip 302-2 are electrically connected to external circuits/devices/components via the bottom substrate 301. The bottom substrate 301 may be attached to a mainboard where the load (CPU, GPU, etc.) are located, and there may be circuits/devices/components on the mainboard providing the input voltage Vin, the phase control signal 105, and a ground reference GND that provides a common ground for the first power device chip 302-1 and the second power device chip 302-2 via the ground pins PGND.

In the example of FIG. 14, the second end of the connecting pillar 302-3 is connected to the bottom substrate 301 via a first switching terminal SSW1. Furthermore, the connecting pillar 302-3 and the heat sink layer 303-3 are electrically connected to the at least one switching pin PSW1 of the first power device chip 302-1 via conductive traces inside the bottom substrate 301. The second end of the connecting pillar 302-4 is connected to the bottom substrate 301 via a first output voltage terminal SVOUT1. The second end of the connecting pillar 302-5 is connected to the bottom substrate 301 via a second switching terminal SSW2. The connecting pillar 302-5 and the heat sink layer 303-4 are electrically connected to the at least one switching pin PSW2 of the second power device chip 302-2 via conductive traces inside the bottom substrate 301. The second end of the connecting pillar 302-6 is connected to the bottom substrate 301 via a second output voltage terminal SVOUT2. In some embodiments of the present invention, the connecting pillars 302-3, 302-4, 302-5 and 302-6 are soldered to the bottom substrate 301, and the first switching terminal SSW1, the first output voltage terminal SVOUT1, the second switching terminal SSW2 and the second output voltage terminal SVOUT2 are solder pastes connected to the ends of the connecting pillars 302-3, 302-4, 302-5 and 302-6. It should be appreciated that the connecting pillars 302-3, 302-4, 302-5 and 302-6 may be connected to the bottom substrate 301 directly, or by other connecting means known in the art, e.g., the connecting pillars 302-3, 302-4, 302-5 and 302-6 may be protruded out of the bottom surface 302-b of the device substrate 302 and are inserted to grooves of the bottom substrate 301.

As shown in FIG. 14, the first power device chip 302-1 further has signal pins PSIG1 which may be configured to transmit temperature monitoring signal, current monitoring signal, and other necessary signals for communicating between the first power device chip 302-1 and external circuits. The second power device chip 302-2 has signal pins PSIG2 which may be configured to transmit temperature monitoring signal, current monitoring signal, and other necessary signals for communicating between the second power device chip 302-2 and external circuits. In FIG. 14, the driving pin PDRV1 is illustrated as an example of the signal pins PSIG1, and the driving pin PDRV2 is illustrated as an example of the signal pins PSIG2. Other signal pins, like the pins for transmitting the temperature monitoring signal, the current monitoring signal, etc., are not specifically labeled for brevity. The discrete components 302-p together with the first power device chip 302-1 and the second power device chip 302-2 which are molded within the device substrate 302 have connecting terminals on the second surface of the device substrate 302. As shown in the embodiment of FIG. 14, each one of the discrete components 302-p, i.e., the capacitors and the resistors, has two pins or pads exposed on the second surface 302-b of device substrate 302, and is connected to the bottom substrate 301, wherein the discrete components 302-p are electrically connected to the first power device chip 302-1 and the second power device chip 302-2, and external components/circuits via the bottom substrate 301. Persons of ordinary skill in the art should know that the pins shown in FIG. 14 are for illustrating, which should not be limiting the present invention. The pin distribution on the second surface of the device substrate 302 is determined by the requirement of the application specs, and is varying in different applications.

FIG. 15 shows a cross-sectional view illustrating the power module 30 taken along CC′ line of FIG. 10 in accordance with an embodiment of the present invention. FIG. 16 shows a cross-sectional view illustrating the power module 30 taken along DD′ line of FIG. 10 in accordance with an embodiment of the present invention. As shown in FIG. 15, the plurality of pins of the first power device chip 302-1 and the second power device chip 302-2 are represented by the shaded regions shown in FIG. 15 and FIG. 16.

Referring back to FIG. 1, each one of the inductors has a first end coupled to the switching terminal S1 of the corresponding phase and a second end to provide the output voltage Vout. Taking the phase 102-1 as an example, in the power module 30, the switching terminal S1 is coupled to a first end of the inductor L-1 (corresponding to the first end 303-1ae of the first winding 303-1) actually through a path from the first power device chip 302-1 to the first portion 303-1a of the first winding 303-1, wherein the path has a certain resistance causing power loss. Arrows with solid lines in FIGS. 15 and 16 show a current flow path from the first power device chip 302-1 to the first portion 303-1a of the first winding 303-1. As shown in FIG. 15, a current flows from the first power device chip 302-1 to the bottom substrate 301 through the at least one switching pin PSW1, then flows to the connecting pillar 302-3 through the conductive traces inside the bottom substrate 301 and the first switching terminal SSW1, and then flows through the connecting pillar 302-3 to the heat sink layer 303-3. As shown in FIG. 16, the current further flows from the heat sink layer 303-3 to the top heat layer 302-7, and finally through the top heat layer 302-7 to the first portion 303-1a of the first winding 303-1. In the example of FIG. 15, a current flow path from the first power device chip 302-2 to the first portion 303-2a of the first winding 303-2 is similar to the current flow path from the first power device chip 302-1 to the first portion 303-1a of the first winding 303-1, and is not illustrated for brevity of description.

As mentioned before, in the embodiments of the power module 20 shown in FIGS. 2-7, the first end 203-1ae of the first winding 203-1 (corresponding to the first end of the inductor L-1 in FIG. 1) is electrically connected to the at least one switching pin PSW1 (corresponding to the switching terminal S1 in FIG. 1) of the first power device chip 202-1 via the connecting pillar 202-3, the first switching terminal SSW1, and the conductive traces inside the bottom substrate 201. Since the connecting pillar 202-3 is placed next to a short edge of the top surface of the first power device chip 202-1, the conductive traces inside the bottom substrate 201 connect the first switching terminal SSW1 and the at least one switching pin PSW1 along a long edge of the top surface of the first power device chip 202-1, causing the conductive traces inside the bottom substrate 201 to be long, which is not good for reducing package resistance of the power module 20. With regard to the power module 30, since the heat sink layers 303-3 and 303-4 and the top heat layers 302-7 and 302-8 are much thicker than the conductive traces inside the bottom substrate 301, using the heat sink layers 303-3 and 303-4 and the top heat layers 302-7 and 302-8 to conduct current provides the power module 30 with a lower package resistance. Furthermore, in the power module 30, the connecting pillars 302-3 and 302-5 are placed next to the long edge x1 of the top surface 302-1a of the first power device chip 302-1 and the long edge x2 of the top surface 302-2a of the second power device chip 302-2 respectively as mentioned before in FIG. 13, thus the conductive traces inside the bottom substrate 301 connecting the switching pins PSW1 and the first switching terminal SSW1 and the second switching terminal SSW2 are shorter.

Besides, thermal performance of the power module 30 is also enhanced since heat of the power module 30 is mostly dissipated through conductors which have larger area (including the top heat layers 302-7 and 302-8, the heat sink layers 303-3 and 303-4, the first winding 302-1 and the second winding 302-2) than the thin conductive traces.

Still referring to FIGS. 15 and 16, arrows with dashed lines 31-35 show main heat flow paths of the power module 30. As shown by the arrows 31 in FIG. 15, heat produced by the device substrate 302 is dissipated through the connecting pillars 302-3 and 302-5, and then through the heat sink layer 303-3 and the second heat sink layer 303-4. As shown by the arrow 34 in FIG. 16, the heat produced by the device substrate 302 is further dissipated through the connecting pillars 302-4 and 302-6, then through the first winding 303-1 and the second winding 303-2, and through the magnetic core 303-5 to the first surface 303-5a the inductor assembly 303 (the connecting pillar 302-6 and the second winding 303-2 are not shown in FIG. 16). As shown by the arrow 32 in FIG. 15, heat produced by the first power device chip 302-1 is dissipated through the top heat layer 302-7, and then through the heat sink layer 303-3. Since the connecting pillar 302-3 is connected to the at least one switching pin PSW1 via the conductive traces inside the bottom substrate 301 and the first switching terminal SSW1, the heat of the first power device chip 302-1 is further dissipated through the conductive traces inside the bottom substrate 301, the first switching terminal SSW1, the connecting pillar 302-3 and the first winding 303-1 as shown by the arrow 33 in FIG. 15. As shown by the arrow 35 in FIG. 16, the heat produced by the first power device chip 302-1 is further dissipated through the top heat layer 302-7, then through the first winding 303-1, and then through the magnetic core 303-5 to the first surface 303-5a of the inductor assembly 303. Heat of the second power device chip 302-2 is dissipated in the same way with the heat of the first power device chip 302-1, and is not discussed for the brevity of description. It is to be noted that, the arrows 31-33 in FIG. 15 only illustrate the heat flow paths from heat sources to the heat sink layer 303-3 and the heat sink layer 303-4. When the heat produced by the first power device chip 302-1, the second power device chip 302-2 and the device substrate 302 flows to the heat sink layer 303-3 and the heat sink layer 303-4, then the heat is partially further dissipated through the heat sink layer 303-3 and the heat sink layer 303-4 directly to the top of the inductor assembly 303, and partially dissipated through the heat sink layer 303-3 and the heat sink layer 303-4 to the magnetic core 303-5, and then finally to the first surface 303-5a of the inductor assembly 303.

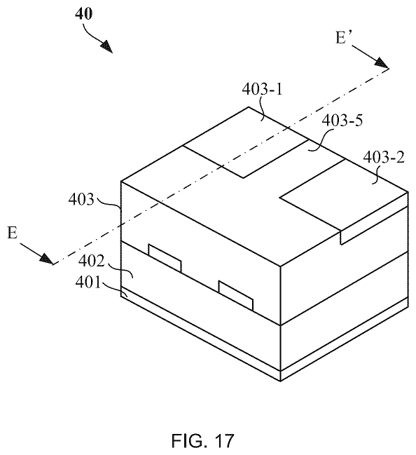

FIG. 17 shows a power module 40 for a dual-phase power converter in accordance with another embodiment of the present invention. The power module 40 may serve as the power stage 102 of FIG. 1, with N=2. The power module 40 includes a bottom substrate 401, a device substrate 402 and an inductor assembly 403. The bottom substrate 401 is arranged at the bottom of the power module 40, having a first surface facing the device substrate 402 and a second surface opposite to the first surface for external connection. The device substrate 402 is arranged on the bottom substrate 401. The inductor assembly 303 is arranged on the device substrate 402, thus the inductors L (e.g., L-1 and L-2) are integrated in the inductor assembly 403. Different from the power modules 20 and 30 illustrated in previous embodiments, a first winding 403-1 and a second winding 403-2 embedded in a magnetic core 403-5 of the inductor assembly 403 also work as heat sinks, thus additional heat sink layers could be omitted in the power module 40.

In one embodiment, the second surface of the bottom substrate 401 of the power module 40 comprises a first output voltage pad area and a second output voltage pad area, an input pad area, a ground pad area and a signal pad area, wherein structure and connection of the pad areas on the second surface of the bottom substrate 401 are same as the pad areas on the second surface 201-b of the bottom surface 201 described previously in FIG. 8, and is not discussed for the brevity of description.

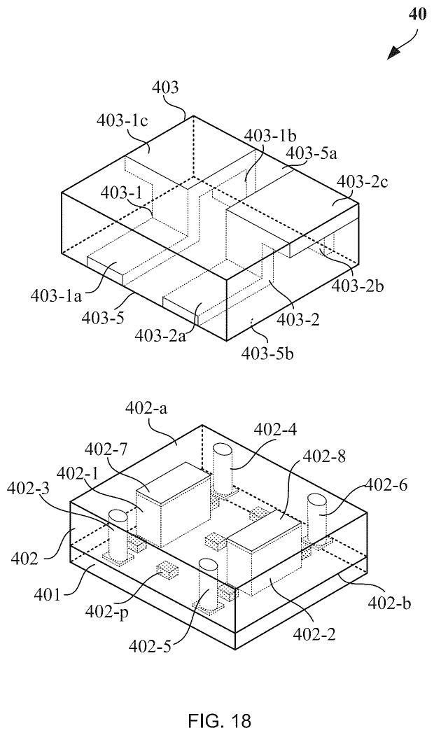

FIG. 18 shows a disassembled and perspective view illustrating the power module 40 of FIG. 17. As shown in FIG. 18, the device substrate 402 has a first surface 402-a and a second surface 402-b opposite to the first surface 302-a, and the device substrate 402 comprises a first power device chip 402-1, a second power device chip 402-2, a top heat layer 402-7 at least partially covering the first power device chip 402-1, and a top heat layer 402-8 at least partially covering the second power device chip 402-2, wherein each of the top heat layers 402-7 and 402-8 has a surface exposed on the first surface 402-a of the device substrate 402. The device substrate 402 further comprises connecting pillars 402-3, 402-4, 402-5, and 402-6, and a plurality of discrete components 402-p, wherein all these components of the device substrate 402 are at least partially embedded in the device substrate 402. Each of the connecting pillars 402-3, 402-4, 402-5, and 402-6 has a first end exposed on the first surface 402-a of the device substrate 402 and a second end exposed on the second surface 402-b of the device substrate 402. Detailed structure and placement of which are same as the connecting pillars 202-3, 202-4, 202-5, and 202-6 and the plurality of discrete components 202-p of the power module 20, and are not discussed for the brevity of description. In the example of FIG. 18, a switching pin of the first power device chip 402-1 is electrically coupled to the top heat layer 402-7 via conductive traces in the bottom substrate 401, the connecting pillar 402-3 and the first winding 403-1, and similarly, a switching pin of the second power device chip 402-2 is electrically coupled to the top heat layer 402-8 via conductive traces in the bottom substrate 401, the connecting pillar 402-5 and the second winding 403-2, which will be further illustrated beginning with FIG. 20.

As shown in FIG. 18, the first winding 403-1 and the second winding 403-2 are at least partially embedded in the magnetic core 403-5, i.e., each of the first winding 403-1 and the second winding 403-2 may have at least one end exposed on one surface of the magnetic core 403-5. The first winding 403-1 and the magnetic core 403-5 form the first inductor L-1 as shown in FIG. 1. The second winding 403-2 and the magnetic core 403-5 form the second inductor L-2 as shown in FIG. 1. In the example shown in FIG. 18, the first winding 403-1 has a first portion 403-1a, a second portion 403-1b, and a third portion 403-1c connecting the first portion 403-1a and the second portion 403-1b. Similarly, the second winding 403-2 has a first portion 403-2a, a second portion 403-2b, and a third portion 403-2c connecting the first portion 403-2a and the second portion 403-2b. The third portion 403-1c of the first winding 403-1 and the third portion 403-2c of the second winding 403-2 are parallel to each other.

As shown in FIG. 18, a top surface of the third portion 403-1c of the first winding 403-1 and a top surface of the third portion 403-2c of the second winding 403-2 are exposed on a first surface 403-5a of the magnetic core 403-5, and each of the first winding 403-1 and the second winding 403-2 has two ends exposed on a second surface 403-5b of the magnetic core 403-5, wherein the second surface 403-5b is opposite to the first surface 403-5a, and the surfaces 403-5a and 403-5b of the magnetic core 403-5 are also referred as surfaces of the inductor assembly 403. In one embodiment, the first winding 403-1 and the second winding 403-2 further have some parts exposed on other surfaces of the magnetic core 403-5. In one embodiment, the first winding 403-1 and the second winding 403-2 are made of copper.

In the example of FIG. 18, when the bottom substrate 401, the device substrate 402 and the inductor assembly 403 are assembled together, the second surface 402-b of the device substrate 402 faces the first surface of the bottom substrate 401, and the second surface 403-5b of the inductor assembly 401 faces the first surface 402-a of the device substrate 402. The first portion 403-1a of the first winding 403-1 is electrically connected to the connecting pillar 402-3 and the top heat layer 402-7, and the second portion 403-1b of the first winding 403-1 is electrically connected to the connecting pillar 402-4. Similarly, the first portion 403-2a of the second winding 403-2 is electrically connected to the connecting pillar 402-5 and the top heat layer 402-8, and the second portion 403-2b of the second winding 403-2 is electrically connected to the connecting pillar 402-6.

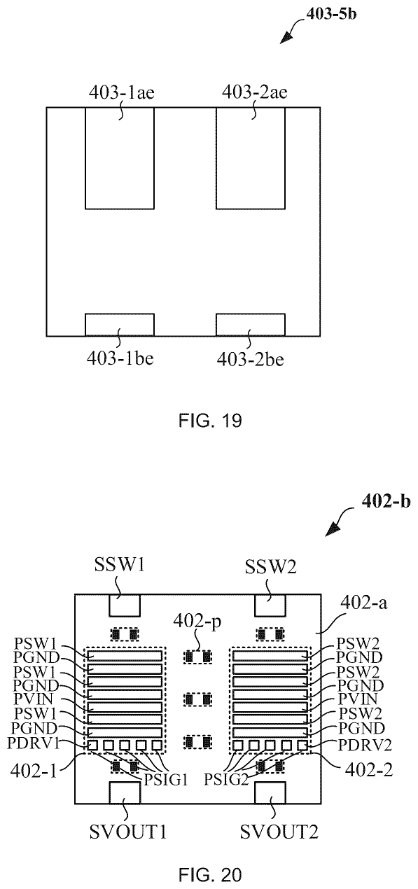

FIG. 19 shows a bottom view of the inductor assembly 403, i.e., the second surface 403-5b of the inductor assembly 403, in accordance with an embodiment of the present invention. In the example shown in FIG. 19, a bottom surface of the first portion 403-1a of the first winding 403-1 forms an end 403-1ae of the first winding 403-1, and a bottom surface of the second portion 403-2a of the second winding 403-2 forms an end 403-2ae of the second winding 403-1. Similarly, a bottom surface of the second portion 403-1b of the first winding 403-1 forms an end 403-1be of the first winding 403-1, and a bottom surface of the second portion 403-2b of the second winding 403-2 forms an end 403-2be of the second winding 403-2. The end 403-1ae of the first winding 403-1 is exposed on the second surface 403-5b of the magnetic core 403-5 as shown in FIG. 19, and is electrically connected to the first end of the connecting pillar 402-3 and the top heat layer 402-7. The end 403-1be of the first winding 403-1 is exposed on the second surface 403-5b of the magnetic core 403-5 as shown in FIG. 19, and is electrically connected to the first end of the connecting pillar 402-4. It should be appreciated that the second winding 403-2 has similar structure with the first winding 403-1 as shown in FIG. 18, i.e., the second winding 403-2 has one end 403-2ae electrically connected to the first end of the connecting pillar 302-5 and the top heat layer 402-8, and has another end 403-2be electrically connected to the first end of the connecting pillar 402-6. In one embodiment, the ends 403-1ae and 403-1be of the first winding 403-1 are physically attached to the first end of the connecting pillar 402-3 and the first end of the connecting pillar 402-4 respectively by soldering or via a conductive adhesive, and the ends 403-2ae and 403-2be of the second winding 403-2 are physically attached to the first end of the connecting pillar 402-5 and the first end of the connecting pillar 402-6 by soldering or via a conductive adhesive.

FIG. 20 shows a bottom view of the device substrate 402, i.e., the second surface 402-b of the device substrate 402, in accordance with an embodiment of the present invention. As mentioned before, each of the first power device chip 402-1 and the second power device chip 402-2 integrates the switches M1, M2, the driver DR1 shown in FIG. 1 and other accessory circuits not shown in FIG. 1. Therefore, each of the first power device chip 402-1 and the second power device chip 402-2 has a plurality of pins which function in the same way with the plurality of pins of the power device chips 202-1 and 202-2 of the power module 20 illustrated in FIG. 7, wherein a common node of the switches M1 and M2 is connected to the at least one switching pin PSW1. In the example of FIG. 20, the device substrate 402 further comprises the first switching terminal SSW1, the second switching terminal SSW2, the first output voltage terminal SVOUT1 and the second output voltage terminal SVOUT2. The connecting pillar 402-3 is connected to the bottom substrate 401 via the first switching terminal SSW1, the connecting pillar 402-4 is connected to the bottom substrate 301 via the first output voltage terminal SVOUT1, the connecting pillar 402-5 is connected to the bottom substrate 401 via the second switching terminal SSW2, and the connecting pillar 402-6 is connected to the bottom substrate 401 via the second output voltage terminal SVOUT2.

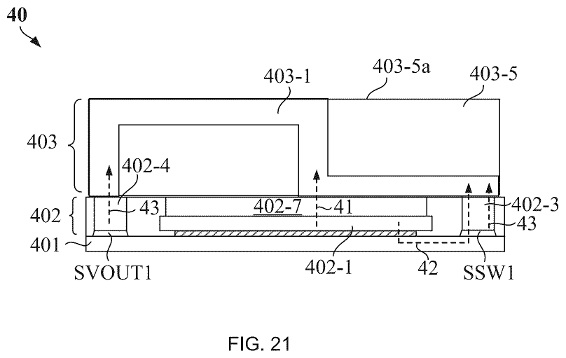

FIG. 21 shows a cross-sectional view illustrating the power module 40 taken along EE′ line of FIG. 17 in accordance with an embodiment of the present invention. As shown in FIG. 21, the first power device chip 402-1 has a first surface partially covered by the top heat layer 402-7 and a second surface connected to the bottom substrate 401 through the plurality of pins as mentioned before in FIG. 20, wherein the plurality of pins are represented by the shaded regions shown in FIG. 21. In the example of FIG. 21, arrows 41-43 with dashed lines show main heat flow paths of the power module 40. As shown by the arrow 41, heat of the power device chip 402-1 is dissipated through the top heat layer 402-7 to the first winding 403-1. Since the connecting pillar 402-3 is connected to the at least one switching pin PSW1 via the conductive traces inside the bottom substrate 401 and the first switching terminal SSW1, the heat of the first power device chip 402-1 is further dissipated through the conductive traces, the first switching terminal SSW1, the connecting pillar 402-3 and the first winding 403-1 as shown by the arrow 42. Heat of the second power device chip 402-2 is dissipated in the same way with the heat of the first power device chip 402-1, and is not discussed for the brevity of description. As shown by the arrows 43 in FIG. 21, heat of the device substrate 402 is dissipated through the connecting pillars 402-3, 402-4, 402-5, and 402-6, the first winding 403-1 and the second winding 403-2 (the connecting pillars 402-5 and 402-6, and the second winding 403-2 are not shown in FIG. 21). Therefore, in the power module 40, the first winding 403-1 and the second winding 403-2 also work as heat sinks conducting both current and thermal, which simplifies the structure of the power module 40 and save cost since no additional heat sink layers are needed. It is to be noted that, the arrows 41-43 in FIG. 21 only illustrate the heat flow paths from heat sources to the windings, when the heat produced by the first power device chip 402-1, the second power device chip 402-2 and the device substrate 402 flows to the first winding 403-1 and the second winding 403-2, then the heat is partially further dissipated through the first winding 403-1 and the second winding 403-2 directly to the first surface 403-5a of the inductor assembly 403, and partially further dissipated through the first winding 403-1 and the second winding 403-2 to the magnetic core 403-5, and then finally to the first surface 403-5a of the inductor assembly 403.

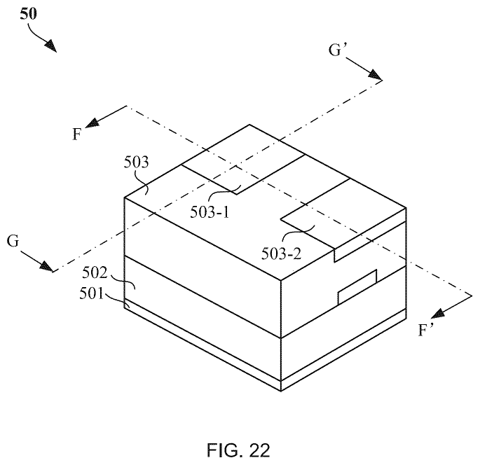

FIG. 22 shows a power module 50 for a dual-phase power converter in accordance with another embodiment of the present invention. The power module 50 may serve as the power stage 102 of FIG. 1, with N=2. The power module 50 includes a bottom substrate 501, a device substrate 502 and an inductor assembly 503. The bottom substrate 501 is arranged at the bottom of the power module 50, having a first surface facing the device substrate 502 and a second surface opposite to the first surface for external connection. The device substrate 502 is arranged on the bottom substrate 501. The inductor assembly 503 is arranged on the device substrate 502, thus the inductors L are integrated in the inductor assembly 503. Similar to the power module 40, additional heat sink layers are omitted in the power module 50.

In one embodiment, the second surface of the bottom substrate 501 of the power module 50 comprises a first output voltage pad area and a second output voltage pad area, an input pad area, a ground pad area and a signal pad area, wherein structure and connection of the pad areas on the second surface of the bottom substrate 501 are same as the pad areas on the second surface 201-b of the bottom substrate 201 described previously in FIG. 8, and is not discussed for the brevity of description.

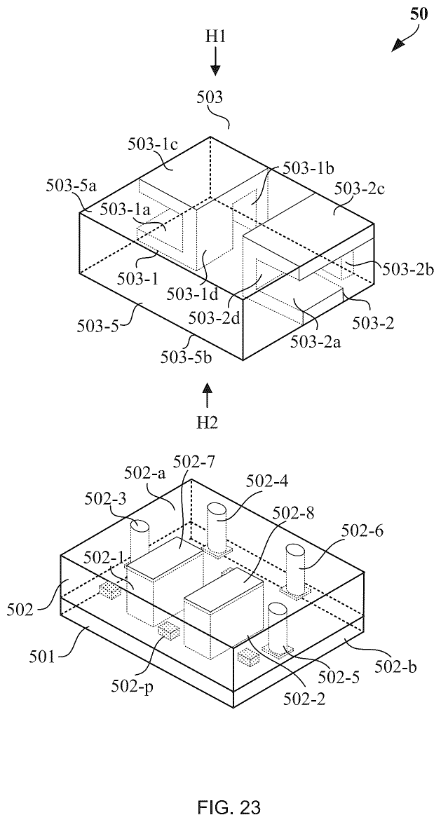

FIG. 23 shows a disassembled and perspective view illustrating the power module 50 of FIG. 22. As shown in FIG. 23, the device substrate 502 has a first surface 502-a and a second surface 502-b opposite to the first surface 502-a, and the device substrate 502 comprises a first power device chip 502-1, a second power device chip 502-2, a top heat layer 502-7 at least partially covering the first power device chip 502-1, a top heat layer 502-8 at least partially covering the second power device chip 502-2, connecting pillars 502-3, 502-4, 502-5, and 502-6, and a plurality of discrete components 502-p, wherein all these components of the device substrate 502 are at least partially embedded in the device substrate 502. Each of the connecting pillars 502-3, 502-4, 502-5, and 502-6 has a first end exposed on the first surface 502-a of the device substrate 502. In the example of FIG. 23, a switching pin of the first power device chip 502-1 is electrically coupled to the top heat layer 502-7 via the device substrate, the bottom substrate, the connecting pillar 502-3 and the first winding 502-1, and similarly, a switching pin of the second power device chip 502-2 is electrically coupled to the top heat layer 502-8 via the device substrate, the bottom substrate, the connecting pillar 502-5 and the second winding 502-2, which will be further illustrated beginning with FIG. 25. Detailed structure of the device substrate 502 is same as the device substrate 302 of the power module 30, and is not discussed for the brevity of description.

As shown in FIG. 23, the first winding 503-1 and the second winding 503-2 are at least partially embedded in the magnetic core 503-5, i.e., each of the first winding 403-1 and the second winding 403-2 may have at least one end exposed on one surface of the magnetic core 403-5. The first winding 503-1 and the magnetic core 503-5 form the first inductor L-1 as shown in FIG. 1. The second winding 503-2 and the magnetic core 503-5 form the second inductor L-2 as shown in FIG. 1. The magnetic core 503-5 has a first surface 503-5a and a second surface 503-5b opposite to the first surface 503-5a, and the surfaces of the magnetic core 503-5 are also referred as surfaces of the inductor module 503. In the example shown in FIG. 23, the first winding 503-1 has a first portion 503-1a, a second portion 503-1b, a third portion 503-1c, and a fourth portion 503-1d, wherein the first portion 503-1a has a bottom surface exposed on the second surface 503-5b of the magnetic core 503-5, the first portion 503-1a and the third portion 503-1c are connected via the fourth portion 503-1d which is inside the magnetic core 503-5, and the second portion 503-1b is connected to the third portion 503-1c and has a bottom surface exposed on the second surface 503-5b of the magnetic core 503-5. Similarly, the second winding 503-2 has a first portion 503-2a, a second portion 503-2b, a third portion 503-2c, and a fourth portion 503-2d which are connected in the same way with the first winding 503-1. As shown in FIG. 23, a top surface of the third portion 503-1c of the first winding 503-1 and a top surface of the third portion 503-2c of the second winding 503-2 are exposed on the first surface 503-5a of the magnetic core 503-5, and the fourth portions 503-1d and 503-2d are vertical to the first surface 503-5a of the magnetic core 503-5. In one embodiment, the first winding 503-1 and the second winding 503-2 further has some parts exposed on other surfaces of the magnetic core 503-5. In a vertical view of the inductor assembly 503 (i.e., viewed from a direction which is perpendicular to the first surface 503-5a of the inductor assembly 503, e.g., in the direction of an arrow H1 or an arrow H2 shown in FIG. 23), the first portion 503-1a and the third portion 503-1c of the first winding 503-1 are at least partially overlapped, and the first portion 503-2a and the third portion 503-2c of the second winding 503-2 are at least partially overlapped. In one embodiment, the first winding 503-1 and the second winding 503-2 are made of copper.

In the example of FIG. 23, when the bottom substrate 501, the device substrate 502 and the inductor assembly 503 are assembled together, the first portion 503-1a of the first winding 503-1 is electrically connected to both the connecting pillar 502-3 and the top heat layer 502-7, and the second portion 503-1b of the first winding 503-1 is electrically connected to the connecting pillar 502-4. Similarly, the first portion 503-2a of the second winding 503-2 is electrically connected to both the connecting pillar 502-5 and the top heat layer 502-8, and the second portion 503-2b of the second winding 503-2 is electrically connected to the connecting pillar 502-6.

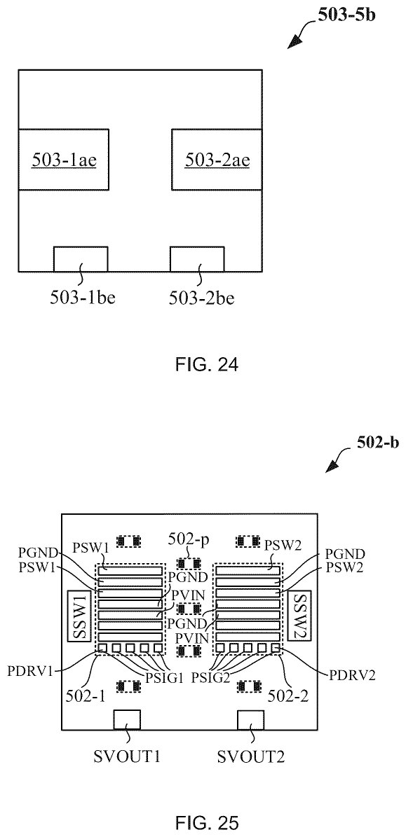

FIG. 24 shows a bottom view of the inductor assembly 503, i.e., the second surface 503-5b of the inductor assembly 503, in accordance with an embodiment of the present invention. As shown in FIG. 24, the bottom surface of the first portion 503-1a of the first winding 503-1 forms an end 503-1ae of the first winding 503-1, and the bottom surface of the second portion 503-2a of the second winding 503-2 forms an end 503-2ae of the second winding 503-1. The bottom surface of the second portion 503-1b of the first winding 503-1 forms an end 503-1be of the first winding 503-1, and the bottom surface of the second portion 503-2b of the second winding 503-2 forms an end 503-2be of the second winding 503-2. The end 503-1ae of the first winding 503-1 is exposed on the second surface 503-5b of the magnetic core 503-5 as shown in FIG. 24, and is physically attached to the surface of the top heat layer 502-7 and the first end of the connecting pillar 502-3 by soldering or via a conductive adhesive. The end 503-1be of the first winding 503-1 is exposed on the second surface 503-5b of the magnetic core 503-5 as shown in FIG. 24, and is physically attached to the first end of the connecting pillar 502-4 by soldering or via a conductive adhesive. Similarly, the end 503-2ae of the second winding 503-2 is physically attached to the surface of the top heat layer 502-8 and the first end of the connecting pillar 502-5 by soldering or via a conductive adhesive, and the end 503-2be of the second winding 503-2 is physically attached to the first end of the connecting pillar 502-6 by soldering or via a conductive adhesive.

FIG. 25 shows a bottom view of the device substrate 502, i.e., the second surface 502-b of the device substrate 502, in accordance with an embodiment of the present invention. As shown in FIG. 25, each of the first power device chip 502-1 and the second power device chip 502-2 has a plurality of pins which function in the same way with the plurality of pins of the power device chips 302-1 and 302-2 of the power module 30 illustrated in FIG. 14, and are not discussed for the brevity of description. In the example of FIG. 25, the device substrate 502 further comprises the first switching terminal SSW1, the second switching terminal SSW2, the first output voltage terminal SVOUT1 and the second output voltage terminal SVOUT2. The connecting pillar 502-3 is connected to the bottom substrate 501 via the first switching terminal SSW1, the connecting pillar 502-4 is connected to the bottom substrate 501 via the first output voltage terminal SVOUT1, the connecting pillar 502-5 is connected to the bottom substrate 501 via the second switching terminal SSW2, and the connecting pillar 502-6 is connected to the bottom substrate 501 via the second output voltage terminal SVOUT2.

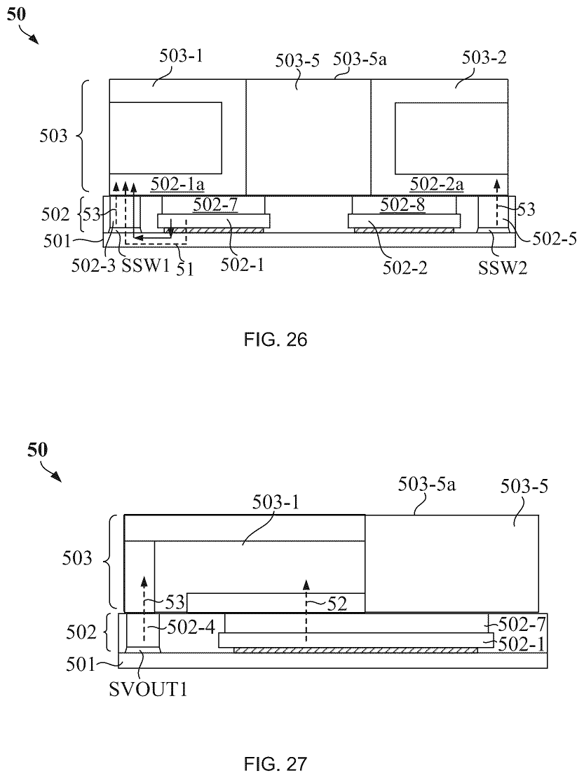

FIG. 26 shows a cross-sectional view illustrating the power module 50 taken along FF′ line of FIG. 22 in accordance with an embodiment of the present invention. FIG. 27 shows a cross-sectional view illustrating the power module 30 taken along GG′ line of FIG. 22 in accordance with an embodiment of the present invention. As shown in FIG. 26, the first power device chip 502-1 has a first surface covered by the top heat layer 502-7 and a second surface connected to the bottom substrate 501 through the plurality of pins as mentioned before in FIG. 25, and the second power device chip 502-2 has a first surface covered by the top heat layer 502-8 and a second surface connected to the bottom substrate 501 through the plurality of pins, wherein the plurality of pins are represented by the shaded regions shown in FIG. 26 and FIG. 27.

Arrows with solid lines in FIG. 26 show a current flow path from the first power device chip 502-1 to the first portion 503-1a of the first winding 503-1 of the power module 50. As shown in FIG. 26, current flows from the first power device chip 502-1 to the bottom substrate 501 through the at least one switching pin PSW1, then flows to the connecting pillar 502-3 through the conductive traces inside the bottom substrate 501 and the first switching terminal SSW1, and then flows through the connecting pillar 502-3 to the first portion 503-1a of the first winding 503-1.

In the example of FIGS. 26 and 27, arrows 51-53 with dashed lines show main heat flow paths of the power module 50. Since the connecting pillars 502-3 is connected to the at least one switching pin PSW1 of the first device chip 502-1 via the conductive traces inside the bottom substrate 501 and the first switching terminal SSW1, heat of the first power device chip 502-1 is dissipated through the conductive traces, the first switching terminal SSW1, the connecting pillar 502-3 and the first winding 503-1 as shown by the arrow 51. As shown by the arrow 52 in FIG. 27, the heat of the first power device chip 502-1 is further dissipated through the top heat layer 502-7 and then through the first winding 503-1. Heat of the second power device chip 502-2 is dissipated in the same way with the heat of the first power device chip 502-1, and is not discussed for the brevity of description. As shown by the arrows 53 in FIGS. 26 and 27, heat of the device substrate 502 is dissipated through the connecting pillars 502-3, 502-4, 502-5, and 502-6, the first winding 503-1, and the second winding 503-2 (the connecting pillar 502-6 is not shown in FIG. 27). It is to be noted that, the arrows 51-53 only illustrate the heat flow paths from heat sources to the windings, when the heat produced by the first power device chip 502-1, the second power device chip 502-2 and the device substrate 502 flows to the first winding 503-1 and the second winding 503-2, then the heat is partially dissipated through the first winding 503-1 and the second winding 503-2 directly to the first surface 503-5a of the inductor assembly 503, and partially dissipated through the first winding 503-1 and the second winding 503-2 to the magnetic core 503-5, and then finally to the first surface 503-5a of the inductor assembly 503.

Similar to the power module 40, the first winding 503-1 and the second winding 503-2 of the power module 50 also work as heat sinks conducting both current and thermal, which simplifies the structure of the power module 50 and save cost since no additional heat sink layers are needed. Besides, since the connecting pillars 502-3 and 502-5 are placed next to the long edges of top surfaces of the first power device chip 502-1 and the second power device chip 502-2, the power module 50 also provides shorter heat flow paths along the conductive traces inside the bottom substrate 501, which means the thermal performance of the power module 50 is also enhanced similar to the power module 30.

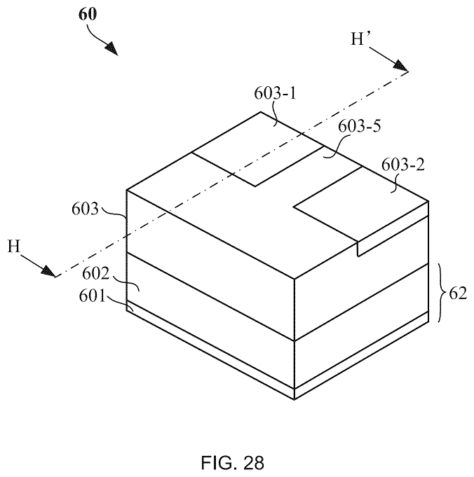

FIG. 28 shows a power module 60 for a dual-phase power converter in accordance with an embodiment of the present invention. The power module 60 may serve as the power stage 102 of FIG. 1, with N=2. The power module 60 comprises an inductor assembly 603, and a device assembly 62 positioned beneath the inductor assembly 603, including a die substrate 601 and a middle substrate 602. The die substrate 601 is arranged at the bottom of the power module 60, the middle substrate 602 is arranged on the die substrate 601. The inductor assembly 603 is arranged on the middle substrate 602, comprising a first winding 603-1 and a second winding 603-2 partially exposed on a top surface of the inductor assembly 603. The device assembly 62 has a top surface attached to a bottom surface of the inductor assembly 603, and has a bottom surface opposite its top surface for external connection. Similar to the power modules 40 and 50, heat sink layers are omitted in the power module 60. In one embodiment, the die substrate 601 is a PCB, and the middle substrate 602 is formed by molding all components which are disposed on the die substrate 601 together.

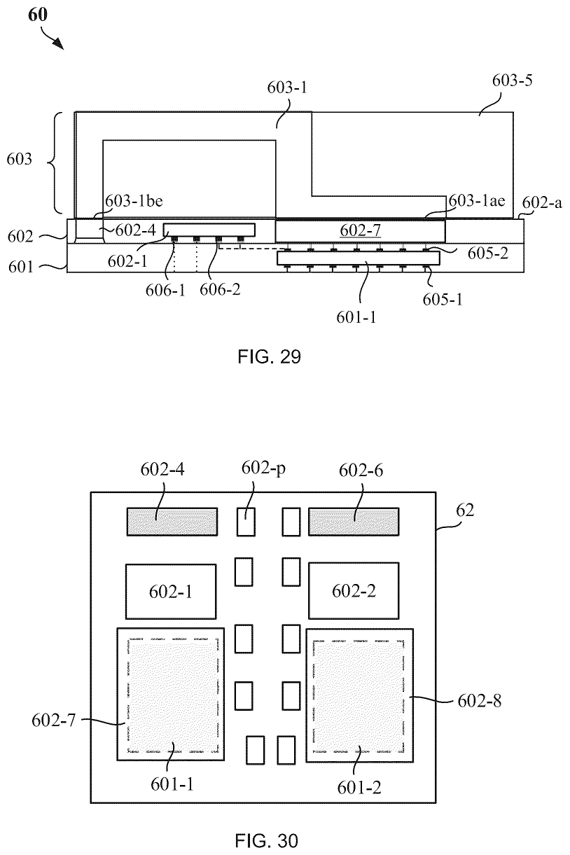

FIG. 29 shows a cross-sectional view illustrating the power module 60 taken along HH′ line of FIG. 28 in accordance with an embodiment of the present invention. The first winding 603-1 and the second winding 603 have similar geometry with the first winding 403-1 and the second winding 403-2 of the power module 40 shown in previous embodiments, which are not described in detail for brevity. Different from the embodiments of the power modules 20-50, for each phase of the power module 60, the switches M1 and M2 are each integrated into separate power dies. As shown in FIG. 29, the power module 60 has two power dies 602-1 and 601-1 for implementing the switches M1 and M2 of the phase 102-1. The switch M1, used as a high side switch of the phase 102-1, is integrated into the power die 602-1, and the switch M2, used as a low side switch of the phase 102-1, is integrated into the power die 601-1. Similarly, though not shown in FIG. 29, the power module 60 further has two power dies 602-2 and 601-2 which respectively integrate the switches M1 and M2 of the phase 102-2.

The power module 60 further incorporates a top heat layer 602-7 disposed in the middle substrate 602, positioned directly above the power die 601-1. In other words, the power die 601-1 is at least partially covered by the top heat layer 602-7. The top heat layer 602-7 is a heat disposal layer, which is made of copper in one embodiment. However, one with ordinary skills in the art should appreciate that any layer that is configured to conduct heat from the power die may serve as the top heat layer. In the embodiment of FIG. 29, the top heat layer 602-7 has a first surface exposed on a first surface 602-a of the middle substrate 602 and has a second surface soldered to the die substrate 601. The first surface of the top heat layer 602-7 is attached to an end 603-1ae of the first winding 603-1, e.g., by soldering. Similarly, though not shown in FIG. 29, the power module 60 further has a top heat layer 602-8 for heat dissipation of the power die 601-2 of the phase 102-2. In some embodiments, there are also top heat layers in the middle substrate 602 respectively covering at least partial of the power die 602-1 and at least partial of the power die 602-2 for heat dissipation of the power dies 602-1 and 602-2.

In the embodiment of FIG. 29, the power die 602-1 is a lateral power device while the power die 601-1 is a vertical power device. In the embodiments of the present disclosure, a lateral power device refers to a power device integrating at least one power switch, wherein the device's metal contacts (e.g., pads, bumps, or pins, etc.) are provided exclusively on a single side of the device. As shown in FIG. 29, the power die 602-1 has a plurality of metal contacts (e.g., bumps, represented by the black squares) on its bottom side. In one embodiment, the power die 602-1 is soldered on the die substrate 601 via its bumps, wherein the grey rectangles beneath each bump represent solder paste. In the embodiments of the present disclosure, a vertical power device refers to a power device integrating at least one power switch, wherein the device's metal contacts are provided on both a top side and a bottom side of the device, enabling the device to deliver power in a vertical direction. E.g., the vertical power devices in the present embodiment (the power die 601-1) has pads on both its top side and bottom side, wherein the top side and bottom side here are two opposite sides of a die. As shown in FIG. 29, the power die 601-1 has a plurality of pads 605-1 (only one of the plurality of pads 605-1 is labelled in FIG. 29 for clarity of illustration) on its bottom side and a plurality of pads 605-2 (only one of the plurality of pads 605-2 is labelled in FIG. 29 for clarity of illustration) on its top side. In one embodiment, each of the plurality of pads 605-1 and the plurality of pads 605-2 of the power die 601-1 is a thin copper layer with a thickness of several micrometers, e.g., less than 10 um. In one embodiment, the driver DR1 and some auxiliary circuits not shown in FIG. 1 are also integrated in the power die 602-1, and in a further embodiment, the controller 101 is also integrated in the power die 602-1. In another embodiment, the driver and/or the controller may be integrated in an individual die.

In the embodiment of FIG. 29, the power die 601-1 is embedded in the die substrate 601. The plurality of pads 605-2 are electrically connected to the first terminal of the switch M2, and the plurality of pads 605-1 are electrically connected to the second terminal of the switch M2. In one embodiment, the switches M1 and M2 are metal-oxide-semiconductor field-effect transistors (MOSFETs), wherein the first terminal of the switch M2 is a Drain terminal and the second terminal of the switch M2 is a Source terminal. The power die 602-1 has a plurality of bumps 606-2 electrically connected to the plurality of pads 605-1 via a conductive path represented by the dashed lines in the die substrate 601 to form a switch node (i.e., the switching terminal S1 of the phase 102-1 shown in FIG. 1). A plurality of bumps 606-1 of the power die 602-1 are electrically connected to a bottom surface of the power module 60 via a conductive path represented by the dotted lines in the die substrate 601 to receive the input voltage Vin. The plurality of pads 605-1 of the power die 601-1 are electrically connected to the bottom surface of the power module 60 via a conductive path represented by the solid lines to provide electrical contacts for the ground reference. The plurality of pads 605-2 of the power die 601-1 are electrically connected to the top heat layer 602-7 via a conductive path represented by the double lines, thus the top heat layer 602-7 and the first winding 603-1 are also electrically connected to the switching terminal S1. One with ordinary skills in the art should understand that all the lines in FIG. 29 which represent corresponding conductive paths are only for illustrative purposes. In some embodiments, the conductive paths may comprise conductive traces, vias, and copper layer, etc.

The embodiment of FIG. 29 utilizes a lateral power device to implement the high side switch and utilizes a vertical power device to implement the low side switch only for illustration purposes, and in another embodiment, the high side switch may be a vertical power device and the low side switch is a lateral power device. The use of the vertical power device provides the power module with a vertical power path together with the top heat layer and the winding. That is to say, compared with the horizontal PCB conductive traces which are necessary for connecting the switch node of a lateral device upwards, the metal contacts of the vertical power device which form the switch node are electrically connected to the winding directly in a vertical direction with shortened conductive traces, which reduces path impedance of the power module. Moreover, the combination of the vertical power device, the top heat layer, and the winding also provides a shortened heat dissipation path toward top of the power module, thereby improving the thermal performance of the power module. In some applications, an external heat sink could be placed on top of the power module to further dissipate the heat.

As shown in FIG. 29, the power module 60 further has a connecting pillar 602-4 in the middle substrate 602, and the connecting pillar 602-4 has an end exposed on the first surface 602-a of the middle substrate 602. An end 603-1be of the first winding 603-1 is exposed on a second surface 603-5b of the inductor assembly 603. The first winding 603-1 is electrically connected to the connecting pillar 602-4 by attaching its end 603-1be to the first end of the connecting pillar 402-4, and the connecting pillar 602-4 is further electrically connected to at least one pad on the bottom surface of the power module 60 to provide the output voltage Vout. Similarly, though not shown in FIG. 29, the power module 60 further has a connecting pillar 602-6 providing conductive paths for the second winding 603-2. The electrical connection of the power dies 602-2 and 601-2 and the second winding 603-2 are similar to that of the power dies 602-1 and 601-1 and the first winding 603-1, which is not described here for brevity.

FIG. 30 shows a top perspective view of the device assembly 62 in accordance with an embodiment of the present invention. As shown in FIG. 30, main components of the phase 102-2, including the connecting pillar 602-6, the power dies 602-2 and 601-2, and the top heat layer 602-8, are placed symmetrically with those of the phase 102-1, but the present disclosure is not limited thereto. In the top perspective view shown in FIG. 30, the top heat layer 602-7 has a larger area than the power die 601-1, i.e., the top heat layer 602-7 completely covers the power die 601-1, and the top heat layer 602-8 completely covers the power die 601-2 in the same way. However, as mentioned before, in other examples, the top heat layer 602-7 and the top heat layer 602-8 may only cover partial of the power die 601-1 and the power die 601-2 respectively. It is shown in FIG. 30 that the power module 60 further has a plurality of passive devices 602-p (e.g., resistors for the drivers DR1, and filter capacitors, etc.) in the device assembly 62. It should be noted that not all of the passive devices 602-p are labeled in FIG. 30 for clarity of illustration, and the layout of the passive devices 602-p is not limited by the example shown in FIG. 30.

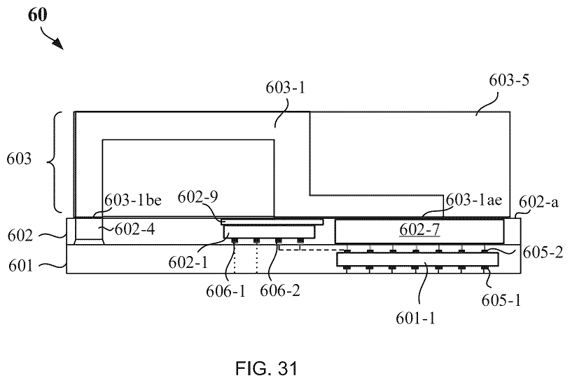

FIG. 31 shows an alternative embodiment illustrating internal structure of the power module 60 of FIG. 28, which is a cross-sectional view illustrating the power module 60 taken along HH′ line of FIG. 28 in accordance with another embodiment of the present invention. As shown in FIG. 31, the end 603-1ae of the winding 603-1 is attached to both the top heat layer 602-7 and a top heat layer 602-9 covering at least partial of the power die 602-1. Similarly, though not shown in FIG. 31, the end 603-2ae of the winding 603-2 is attached to both the top heat layer 602-10 disposed on the power die 602-2 and the top heat layer 602-8 disposed on the power die 601-1. Compared with the embodiment shown in FIGS. 28-30, the power module 60 of FIG. 31 further provides a heat dissipation path from the power die 602-1 to the top of the power module 60, thereby further improving the thermal performance of the power module 60.

It is to be noted that, although FIGS. 28-31 illustrate a dual-phase power module, as noted in the description of FIG. 1, the present invention can also be applied to a single-phase power module or a multi-phase power module with more than two phases.

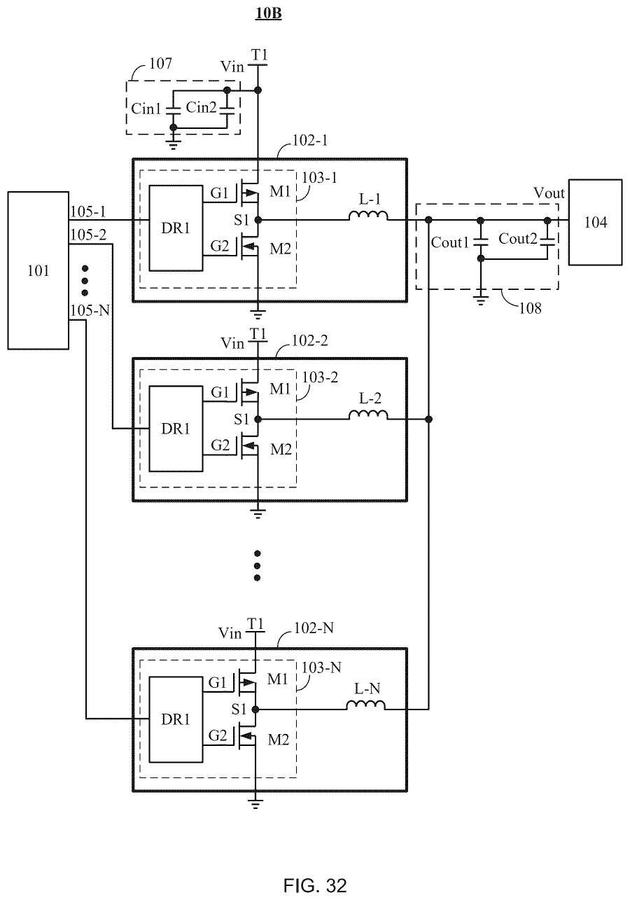

FIG. 32 schematically shows a multi-phase power converter 10B in accordance with an embodiment of the present invention. Compared with the multi-phase power converter 10 shown in FIG. 1, the multi-phase power converter 10B further has an input capacitor pack 107 and an output capacitor pack 108. The input capacitor pack 107 has a plurality of capacitors coupled in parallel between the input terminal T1 and the ground reference. The output capacitor pack 108 has a plurality of capacitors coupled in parallel between an output terminal and the ground reference. The embodiment of FIG. 32 shows two capacitors Cin1 and Cin2 in the input capacitor pack 107 and two capacitors Cout1 and Cout2 in output capacitor pack 108 as one example. However, one with ordinary skills in the art should understand that the number of the capacitors included in the input capacitor pack 107 and the number of the capacitors included in the output capacitor pack 108 are not limited by FIG. 32.

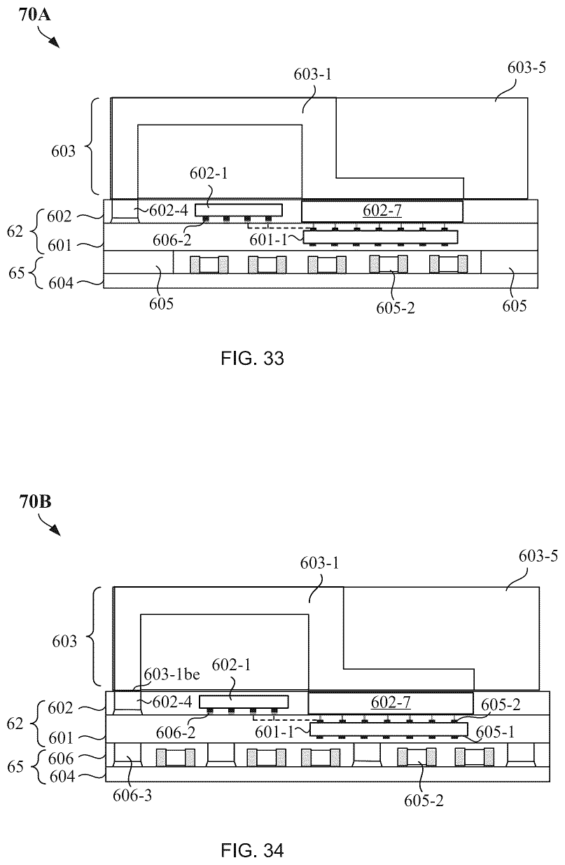

FIGS. 33-36 illustrate, in cross-section, power modules 70A-70D in accordance with embodiments of the present invention that implement the power converter 10B of FIG. 32. The power modules 70A-70D have a capacitor layer beneath the device assembly. The sectional planes and viewing orientation shown in FIGS. 33-36 are identical to those of FIG. 29. As mentioned before, the present invention shown in the embodiments of FIGS. 33-36 can be applied to a single-phase power module, a dual-phase power module, or a multi-phase power module with at least three phases.

FIG. 33 shows the cross-sectional view illustrating the power module 70A. Compared with the power module 60, the power module 70A further has a capacitor layer 65 disposed on the bottom of the power module 70A, below the device assembly 62 with a top surface attached to the bottom surface of the device assembly 62. As shown in FIG. 33, the capacitor layer 65 has a bottom substrate 604 and a PCB frame 605, and in one embodiment, the bottom substrate 604 is also made of PCB. The PCB frame 605 is stacked on the bottom substrate 604 to form at least one cavity or other carved out regions to accommodate a plurality of capacitors 605-2 (only one of the plurality of capacitors 605-2 is labelled in FIG. 33 for clarity of illustration) which are soldered on the bottom substrate 604. A first portion of the plurality of capacitors 605-2 are electrically connected in parallel to implement the input capacitor 107 shown in FIG. 32, and a second portion of the plurality of capacitors 605-2 are electrically connected in parallel to implement the output capacitor 108 shown in FIG. 32. The PCB frame 605 and the bottom substrate 604 provide conductive paths for electrically connecting the plurality of capacitors 605-2 with the components in the inductor assembly 603 and the device assembly 62, and also provide conductive paths for receiving the input voltage Vin and providing the output voltage Vout.

FIG. 34 shows the cross-sectional view illustrating the power module 70B. Different from the power module 70A, a plurality of connecting pillars 606-3 soldered on the bottom substrate 604 are configured to provide the conductive paths which are provided by the PCB frame 605 in FIG. 33. In the example of FIG. 34, the connecting pillars 606-3 and the plurality of capacitors 605-2 are molded together to form a capacitor substrate 606, and in another embodiment, the capacitor substrate 606 is open frame with no molding compound. In some embodiments, capacitor layer 65 may comprise both the connecting pillars 606-3 and the PCB frame 605, wherein the connecting pillars 606-3 are for power delivery and the PCB frame 605 is configured to transmit signals, including the temperature monitoring signal, and the current monitoring signal, etc. In one embodiment, at least one of the plurality of connecting pillars 606-3 is disposed under the power die 601-1 to minimize the conductive paths for providing the ground reference, and at least one of the plurality of connecting pillars 606-3 is disposed under the power die 602-1 to minimize the conductive paths for receiving the input voltage Vin, and at least one of the plurality of connecting pillars 606-3 is disposed under the second end 603-1be of the first winding 603-1 to minimize the conductive paths for providing the output voltage Vout.

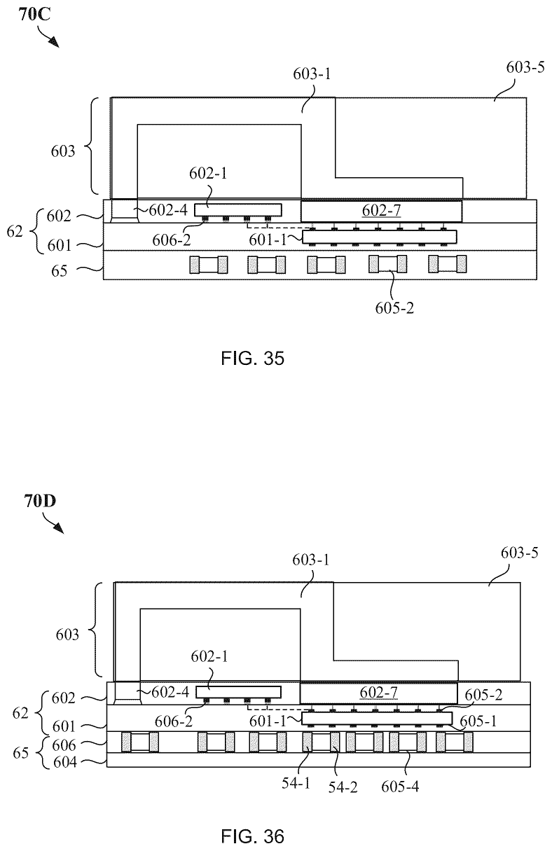

FIG. 35 shows the cross-sectional view illustrating the power module 70C. In the embodiment of FIG. 35, the device assembly 65 is formed by embedding the plurality of capacitors 605-2 in a substrate, e.g., a PCB.

FIG. 36 shows the cross-sectional view illustrating the power module 70D. As shown in FIG. 36, the capacitor substrate 606 has a plurality of capacitors 605-4 (only one of the plurality of capacitors 605-4 is labeled for clarity of illustration), and each of the capacitors 605-4 has two terminals. In the embodiment of FIG. 36, terminals of the capacitors 605-4 are configured as vias to conduct current, e.g., between the bottom substrate 604 and the die substrate 601. As labeled in one of the plurality of capacitors 605-4, each capacitor has two terminals 54-1 and 54-2. The terminals 54-1 and 54-2 are extended between the bottom substrate 604 and the die substrate 601, and each of the terminals 54-1 and 54-2 form a metal contact (e.g., a pad) on both its top side and bottom side for current conduction. The capacitor layer 606 may be molded or open frame. In one embodiment, the capacitor layer 606 may further comprise connecting pillars, or a PCB frame, or both.

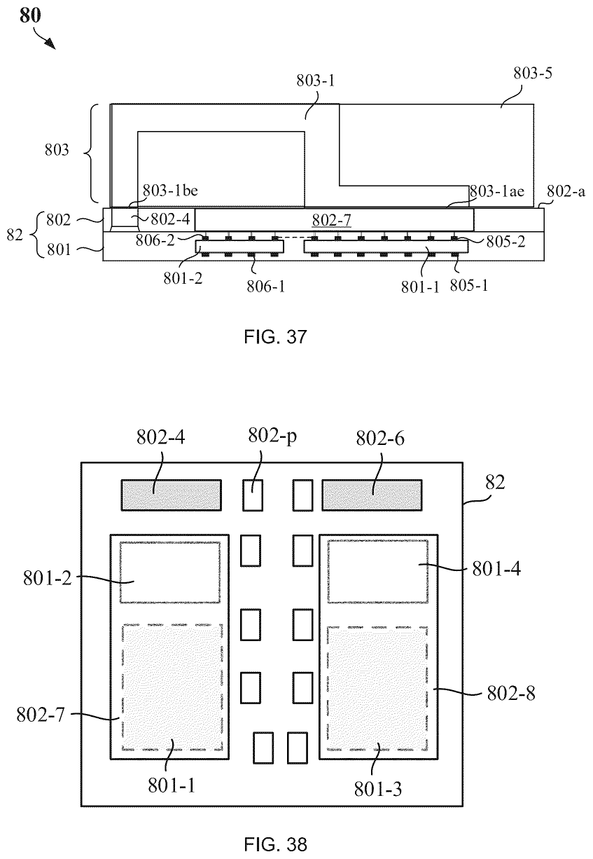

FIG. 37 shows a cross-sectional view illustrating a power module 80 in accordance with another embodiment of the present invention. The sectional plane and viewing orientation shown in FIG. 36 are identical to those of FIG. 29. Similar to the power module 60 shown in FIG. 29, the power module 80 comprises an inductor assembly 803, and a device assembly 82 including a die substrate 801 and a middle substrate 802. As shown in FIG. 37, the inductor assembly 803, the middle substrate 802, and the die substrate 801 are stacked in the same way as the corresponding parts of the power module 60 do. The inductor assembly 803 has the same structure with the inductor assembly 603, which is not described here for brevity.

Different from the power module 60, the power module 80 has two power dies 801-1 and 801-2 for the phase 102-1 which are both embedded in the die substrate 801, and both the power dies 801-2 and 801-1 are vertical power devices. In the embodiment of FIG. 37, the switch M1, used as the high side switch of the phase 102-1, is integrated into the power die 801-2, and the switch M2, used as the low side switch of the phase 102-1, is integrated into the power die 801-1. Similarly, though not shown in FIG. 37, the power module 80 further has two power dies 801-4 and 801-3 which respectively integrate the switches M1 and M2 of the phase 102-2. As shown in FIG. 37, the power die 801-1 has a plurality of pads 805-1 (only one of the plurality of pads 805-1 is labelled in FIG. 37 for clarity of illustration) on its bottom side and a plurality of pads 805-2 (only one of the plurality of pads 805-2 is labelled in FIG. 37 for clarity of illustration) on its top side. The power die 801-2 has a plurality of pads 806-1 (only one of the plurality of pads 806-1 is labelled in FIG. 37 for clarity of illustration) on its bottom side and a plurality of pads 806-2 (only one of the plurality of pads 806-2 is labelled in FIG. 37 for clarity of illustration) on its top side. In one embodiment, each pad of the plurality of pads 805-1, 805-2, 806-1, and 806-2 is a thin copper layer with a thickness of several micrometers. In one embodiment, the driver DR1 and the auxiliary circuits are integrated into at least one of the power dies 802-1 and 801-1, and in a further embodiment, the controller 101 is also integrated in at least one of the power dies 802-1 and 801-1. In another embodiment, the driver and/or the controller may be integrated into an individual die.

In the embodiment of FIG. 37, the plurality of pads 805-2 are electrically connected to the first terminal of the switch M2, and the plurality of pads 805-1 are electrically connected to the second terminal of the switch M2. The plurality of pads 806-2 are electrically connected to the plurality of pads 805-2 via a conductive path shown by the dashed line in the die substrate 801 to form the switch node (i.e., the switching terminal S1 of the phase 102-1 shown in FIG. 1). The plurality of pads 806-2 and the plurality of pads 805-2 are further electrically connected to the top heat layer 802-7 via a conductive path shown by the double lines. The plurality of pads 806-1 of the power die 801-2 are electrically connected to the bottom surface of the power module 80 to receive the input voltage Vin. The plurality of pads 805-1 of the power die 801-1 are electrically connected to the bottom surface of the power module 80 to provide electrical contacts for the ground reference. Both the plurality of pads 805-1 of the power die 801-1 and the plurality of pads 806-1 of the power die 801-2 are electrically connected to a top heat layer 802-7 in the middle substrate 802. The top heat layer 802-7 is disposed directly above the power dies 801-1 and 801-2. In other words, both the power die 801-1 and the power die 801-2 are at least partially covered by the top heat layer 802-7. In the embodiment of FIG. 37, the top heat layer 802-7 is heat disposal layers for both the power die 801-1 and the power die 801-2, made of metal. In the embodiment of FIG. 37, the top heat layer 802-7 has a first surface exposed on a first surface 802-a of the middle substrate 802 and has a second surface soldered to the die substrate 801. The first surface of the top heat layer 802-7 is attached to an end 803-1ae of a first winding 803-1, e.g., by soldering. Therefore, the top heat layer 802-7 and the first winding 803-1 are also electrically connected to the switching terminal S1. Similarly, though not shown in FIG. 37, the power module 80 further has a top heat layer 802-8 for heat dissipation of the power dies 801-3 and 801-4 of the phase 102-2.

As shown in FIG. 37, the power module 80 further has a connecting pillar 802-4 in the middle substrate 802, which functions identically to the connecting pillar 602-4 of the power module 60. An end 803-1be is electrically connected to at least one pad on the bottom surface of the power module 80 via the connecting pillar 802-4 to provide the output voltage Vout. Similarly, though not shown in FIG. 37, the power module 80 further has a connecting pillar 802-6 providing conductive paths for the second winding 803-2. The electrical connection between the power dies 801-3 and 801-4 and the second winding 803-2 are similar to that between the power dies 801-1 and 801-2 and the first winding 803-1, which is not described here for brevity.

FIG. 38 shows a top perspective view of the device assembly 82 in accordance with an embodiment of the present invention. As shown in FIG. 38, main components of the phase 102-2, including the connecting pillar 802-6, the power dies 801-3 and 801-4, and the top heat layer 802-8, are placed symmetrically with those of the phase 102-1, but the present disclosure is not limited thereto. In the top perspective view shown in FIG. 38, the top heat layer 802-7 completely covers the power dies 801-1 and 801-2, and the top heat layer 802-8 completely covers the power dies 801-3 and 801-4 in the same way. However, as mentioned before, in other examples, the top heat layer 802-7 may only cover partial of the power dies 801-1 and 801-2, and the top heat layer 802-8 may only cover partial of the power dies 801-3 and 801-4. It is shown in FIG. 38 that the power module 80 further has a plurality of passive devices 802-p (e.g., the resistors for the drivers DR1, and the filter capacitors, etc.) in the device assembly 82. It should be noted that not all of the passive devices 802-p are labeled in FIG. 38 for clarity of illustration, and the layout of the passive devices 802-p is not limited by the example shown in FIG. 38.

It is to be noted that, although FIGS. 37-38 illustrate a dual-phase power module, as noted in the description of FIG. 1, the present invention can also be applied to a single-phase power module or a multi-phase power module with more than two phases.

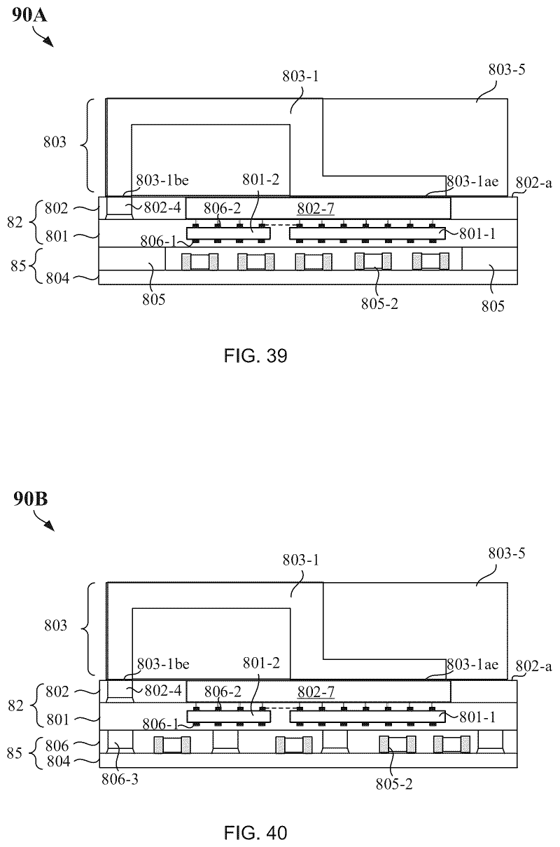

FIGS. 39-42 illustrate, in cross-section, power modules 90A-90D in accordance with embodiments of the present invention that implement the power converter 10B of FIG. 32, having the same die configuration as the power module 80. The sectional planes and viewing orientation shown in FIGS. 39-42 are identical to those of FIG. 36. As mentioned before, the present invention shown in the embodiments of FIGS. 39-42 can be applied to a single-phase power module, a dual-phase power module, or a multi-phase power module with at least three phases.

FIG. 39 shows the cross-sectional view illustrating the power module 90A. Compared with the power module 80, the power module 90A further has a capacitor layer 85 disposed on the bottom of the power module 80A, below the device assembly 82 with a top surface attached to the bottom surface of the device assembly 82. As shown in FIG. 39, similar to the capacitor layer 65 of the power module 60, the capacitor layer 85 has a bottom substrate 804 and a PCB frame 805 stacked on the bottom substrate 804 for accommodating a plurality of capacitors 805-2 (only one of the plurality of capacitors 805-2 is labelled in FIG. 39 for clarity of illustration). A first portion of the plurality of capacitors 805-2 are electrically connected in parallel to implement the input capacitor 107 shown in FIG. 32, and a second portion of the plurality of capacitors 805-2 are electrically connected in parallel to implement the output capacitor 108 shown in FIG. 32.

FIG. 40 shows the cross-sectional view illustrating the power module 90B. The capacitor layer 85 of the power module 90B is similar to that of the power module 70B with the capacitor layer 806 having a plurality of connecting pillars 806-3 soldered on the bottom substrate 804. In one embodiment, at least one of the plurality of connecting pillars 806-3 is disposed under the power die 801-1 to minimize the conductive paths for providing the ground reference, and at least one of the plurality of connecting pillars 806-3 is disposed under the power die 801-2 to minimize the conductive paths for receiving the input voltage Vin, and at least one of the plurality of connecting pillars 806-3 is disposed under the second end 803-1be of the first winding 803-1 to minimize the conductive paths for providing the output voltage Vout. In some embodiments, capacitor layer 85 may comprise both the connecting pillars 806-3 and the PCB frame 80 as mentioned before.

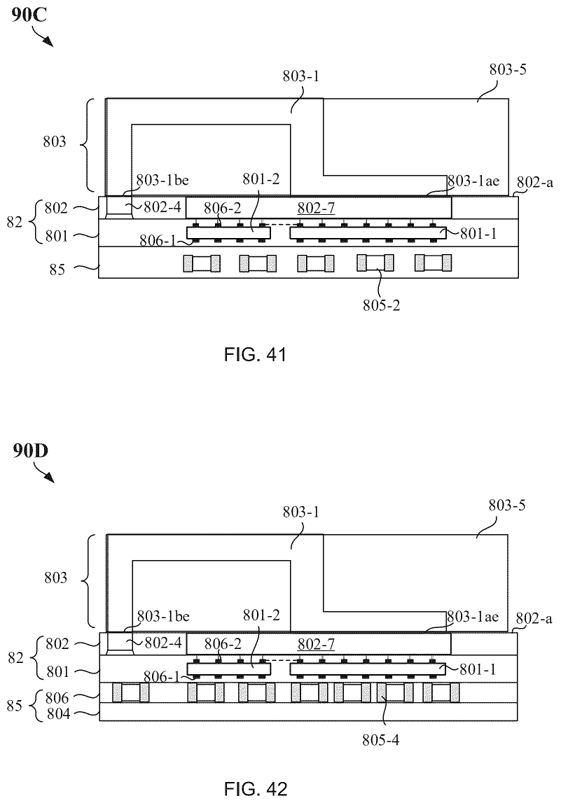

FIG. 41 shows the cross-sectional view illustrating the power module 90C. In the embodiment of FIG. 41, the device assembly 85 is formed by embedding the plurality of capacitors 805-2 in a substrate, e.g., a PCB.

FIG. 42 shows the cross-sectional view illustrating the power module 90D. As shown in FIG. 42, the capacitor substrate 806 has a plurality of capacitors 805-4 (only one of the plurality of capacitors 805-4 is labeled for clarity of illustration). The plurality of capacitors 805-4 function identically to the plurality of capacitors 605-4, which is not described here for brevity. In one embodiment, the capacitor layer 806 may further comprise connecting pillars, or a PCB frame, or both.

In the embodiments shown in FIGS. 33-36 and FIGS. 39-42, the integration of the input and output capacitors under the power dies further brings the power module higher power density. Compared to a power module using only a lateral power device for each phase, the present invention places the high side and low side switches in two separate dies, with at least one die being a vertical power device. This arrangement distributes the metal contacts of the power dies more widely across the die substrate, enabling the input or output capacitors that must be connected to the corresponding net (Vin and GND, or Vout and GND) to be placed at suitable positions under corresponding metal contacts of the power dies to electrically connect to the corresponding metal contacts vertically, and so as to shorten the horizontal conductive paths.

From another perspective, for a power module integrating a capacitor layer beneath the device assembly, the use of at least one vertical power device also brings additional benefits. For example, in FIGS. 33-36, the low side switch is integrated into a vertical power device embedded in the die substrate 601, rather than soldered onto it. Since fewer solder pastes is required, the path impedance of the power module is reduced. Furthermore, in FIGS. 39-42 with both the power dies 801-1 and 801-2 being the vertical power devices embedded in the die substrate 801, the path impedance of the power module is further reduced.

In the embodiments of the present disclosure, each phase of the power module has at least one vertical power device to form the vertical power paths together with the top heat layer and the winding, providing the power module with shorter path impedance and thereby enabling the power module to exhibit better transient response performance.

Obviously many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

What is claimed is:

1. A power module, comprising:
an inductor assembly comprising a magnetic core and a first winding at least partially embedded in the magnetic core, wherein the first winding has a first end and a second end which are exposed on a bottom surface of the inductor assembly, and the first end of the first winding is capable of providing an output voltage;
a device assembly attached to the bottom surface of the inductor assembly, comprising a die substrate, a first power die and a second power die each having a first plurality of metal contacts and a second plurality of metal contacts, wherein the first power die and the second power die respectively integrates a first switch and a second switch which are electrically connected in series; wherein
the first plurality of metal contacts of the first power die and the first plurality of metal contacts of the second power die are electrically connected together and are further electrically connected to the second end of the first winding, wherein the first plurality of metal contacts of the second power die is disposed on a top side of the second power die, and the second power die is embedded in the die substrate; and wherein
the first power die is capable of receiving an input voltage via its second plurality of metal contacts on its bottom side, and the second power die is capable of being electrically connected to a ground reference via its second plurality of metal contacts on its bottom side.

2. The power module of claim 1, wherein the first power die is embedded in the die substrate, and the first plurality of metal contacts of the first power die are disposed on a top side of the first power die.

3. The power module of claim 1, wherein the first power die is soldered on the die substrate, and the first plurality of metal contacts of the first power die are disposed on the bottom side of the first power die.

4. The power module of claim 1, further comprising:
a first top heat layer in the device assembly, wherein the top heat layer is soldered on the die substrate and is disposed directly above the second power die; wherein
the first plurality of metal contacts of the first power die and the first plurality of metal contacts of the second power die are electrically connected to the second end of the first winding via the top heat layer.

5. The power module of claim 4, further comprising:
a second top heat layer in the device assembly, wherein the second top heat layer is disposed directly above the first power die; wherein
the second top heat layer has a surface attached to the second end of the first ending.

6. The power module of claim 1, further comprising:
a second winding embedded in the magnetic core, having a first end and a second end which are exposed on the bottom surface of the inductor assembly, and the first end of the second winding is capable of providing the output voltage by being electrically connected with the first end of the first winding;
a third power die and a fourth power die each having a first plurality of metal contacts and a second plurality of metal contacts, wherein the third power die and the fourth power die respectively integrates a third switch and a fourth switch electrically connected in series; wherein
the first plurality of metal contacts of the third power die and the first plurality of metal contacts of the fourth power die are electrically connected together and are further electrically connected to the second end of the second winding, wherein the first plurality of metal contacts of the fourth power die is disposed on a top side of the fourth power die, and the fourth power die is embedded in the die substrate; and wherein
the third power die is capable of receiving the input voltage via its second plurality of metal contacts on its bottom side, and the fourth power die is capable of being electrically connected to the ground reference via its second plurality of metal contacts on its bottom side.

7. A power module, comprising:
an inductor assembly comprising a magnetic core and a winding at least partially embedded in the magnetic core, wherein the winding has a first end and a second end which are exposed on a bottom surface of the inductor assembly, and the first end of the winding is capable of providing an output voltage;
a device assembly attached to the bottom surface of the inductor assembly, comprising a die substrate, a first power die having a first switch, and a second power die having a second switch, wherein the first switch and the second switch are electrically connected in series between an input voltage and a ground reference; wherein
the second power die is embedded in the die substrate, having a first plurality of metal contacts on its top side and a second plurality of metal contacts on its bottom side; and wherein
a first plurality of metal contacts of the first power die and the first plurality of metal contacts of the second power die are electrically connected together and are further electrically connected to the second end of the winding.

8. The power module of claim 7, wherein:
at least one of the first power die and the second power die is further capable of generating a first driving signal and a second driving signal for respectively driving the first switch and the second switch.

9. The power module of claim 7, wherein:
the first power die further comprises a second plurality of metal contacts, and the first plurality of metal contacts and the second plurality of metal contacts of the first power die are disposed on a bottom side of the first power die; wherein
the first power die is capable of being electrically connected to the input voltage via its second plurality of metal contacts, and the second power die is capable of being electrically connected to the ground reference via its second plurality of metal contacts.

10. The power module of claim 7, wherein:
the first power die further comprises a second plurality of metal contacts, and the first plurality of metal contacts and the second plurality of metal contacts of the first power die are disposed on a bottom side of the first power die; wherein
the second power die is capable of being electrically connected to the input voltage via its second plurality of metal contacts, and the first power die is capable of being electrically connected to the ground reference via its second plurality of metal contacts.

11. The power module of claim 7, wherein:
the first power die is embedded in the die substrate, further comprising a second plurality of metal contacts; wherein
the first plurality of metal contacts of the first power die are disposed on a top side of the first power die, and the second plurality of metal contacts of the first power die are disposed on a bottom side of the first power die.

12. The power module of claim 7, further comprising:
a top heat layer in the device assembly, wherein the top heat layer is disposed directly above at least one of the first power die and the second power die; wherein
the first plurality of metal contacts of the first power die and the first plurality of metal contacts of the second power die are electrically connected to the second end of the winding via the top heat layer.

13. A power module, comprising:
an inductor assembly comprising a magnetic core, a first winding, and a second winding, wherein the first winding and the second winding are at least partially embedded in the magnetic core and each have a first end and a second end which are exposed on a bottom surface of the inductor assembly;
a device assembly attached to the bottom surface of the inductor assembly, comprising a die substrate, a first power die having a first switch, a second power die having a second switch, a third power die having a third switch, and a fourth power die having a fourth switch, wherein the first switch and the second switch are electrically connected in series between an input voltage and a ground reference, and the third switch and the fourth switch are electrically connected in series between the input voltage and the ground reference; wherein
the second power die and the fourth power die are embedded in the die substrate, and each of the second power die and the fourth power die has a first plurality of metal contacts on its top side and a second plurality of metal contacts on its bottom side; and wherein
a first plurality of metal contacts of the first power die and the first plurality of metal contacts of the second power die are electrically connected together and are further electrically connected to the second end of the first winding, and a first plurality of metal contacts of the third power die and the first plurality of metal contacts of the fourth power die are electrically connected together and are further electrically connected to the second end of the second winding.

14. The power module of claim 13, further comprising:
a first top heat layer and a second top heat layer in the device assembly, wherein the first top heat layer is disposed directly above at least one of the first power die and the second power die, and the second top heat layer is disposed directly above at least one of the third power die and the fourth power die; wherein
the first plurality of metal contacts of the first power die and the first plurality of metal contacts of the second power die are electrically connected to the second end of the first winding via the first top heat layer, and the first plurality of metal contacts of the third power die and the first plurality of metal contacts of the fourth power die are electrically connected to the second end of the second winding via the second top heat layer.

15. The power module of claim 13, wherein:
the first power die is soldered on the die substrate, further comprising a second plurality of metal contacts, and the first plurality of metal contacts and the second plurality of metal contacts of the first power die are disposed on a bottom side of the first power die; and
the third power die is soldered on the die substrate, further comprising a second plurality of metal contacts, and the first plurality of metal contacts and the second plurality of metal contacts of the third power die are disposed on a bottom side of the third power die.

16. The power module of claim 13, wherein:
the first power die is embedded in the die substrate, further comprising a second plurality of metal contacts, wherein the first plurality of metal contacts of the first power die are disposed on a top side of the first power die, and the second plurality of metal contacts of the first power die are disposed on a bottom side of the first power die; and
the third power die is embedded in the die substrate, further comprising a second plurality of metal contacts, wherein the first plurality of metal contacts of the third power die are disposed on a top side of the third power die, and the second plurality of metal contacts of the third power die are disposed on a bottom side of the first power die.

17. The power module of claim 13, wherein:
at least one of the first power die and the second power die is further capable of generating a first driving signal and a second driving signal for respectively driving the first switch and the second switch; and
at least one of the third power die and the fourth power die is further capable of generating a third driving signal and a fourth driving signal for respectively driving the third switch and the fourth switch.

18. The power module of claim 13, wherein:
each metal contact of the first plurality of metal contacts and the second plurality of metal contacts of the second power die is a copper layer with a thickness less than 10 um.

19. The power module of claim 13, further comprising:
a capacitor layer disposed beneath the device assembly and attached to a bottom surface of the device assembly; wherein
the first end of the first winding and the first end of the second winding are capable of being electrically connected together to provide an output voltage; and wherein
the capacitor layer comprises a plurality of capacitors, wherein a first portion of the plurality of capacitors are electrically connected in parallel between the input voltage and the ground reference, and a second portion of the plurality of capacitors are electrically connected in parallel between the output voltage and the ground reference.
